(19) United States
(12) Patent Application Publication
(10) Pub. No.: US 2025/0311278 A1
(43) Pub. Date: Oct. 2, 2025

(54) INTEGRATED CIRCUIT DEVICE INCLUDING A FIELD-EFFECT TRANSISTOR

(71) Applicant: SAMSUNG ELECTRONICS CO., LTD., SUWON-SI (KR)

(72) Inventors: Pilkwang KIM, Suwon-si (KR); Seunghyun SONG, Suwon-si (KR); Kyeongrim KIM, Suwon-si (KR); Kyoungyeon KIM, Suwon-si (KR); Gwangjun KIM, Suwon-si (KR); Yonghee PARK, Suwon-si (KR); Youngseok SONG, Suwon-si (KR)

(21) Appl. No.: 18/982,044

(22) Filed: Dec. 16, 2024

(30) Foreign Application Priority Data
Mar. 27, 2024 (KR) 10-2024-0042009

(51) Int. Cl. H10D 30/00; H10D 30/01

(52) U.S. Cl. CPC H10D 30/508; H10D 30/0193; H10D 30/0195; H10D 30/503

(57) ABSTRACT

An integrated circuit device includes: a fin-type active region on a substrate; a nanosheet disposed on the fin-type active region; a gate line surrounding the nanosheet, wherein the gate line overlaps the nanosheet; a source/drain region disposed on the fin-type active region and contacting the nanosheet; and an interface insulating film surrounding the gate line, and including an inner spacer portion disposed between a sidewall of the gate line and the source/drain region, wherein the inner spacer portion includes: a first inner spacer portion protruding toward the source/drain region, while covering the sidewall of the gate line and while spaced apart from the nanosheet, wherein the first inner spacer portion has a first thickness; and a second inner spacer portion extending from the first inner spacer portion toward the nanosheet, wherein the second inner spacer portion has a second thickness that is less than the first thickness.

### CROSS-REFERENCE TO RELATED APPLICATION

This application claims priority under 35 U.S.C. § 119 to Korean Patent Application No. 10-2024-0042009, filed on Mar. 27, 2024, in the Korean Intellectual Property Office, the disclosure of which is incorporated by reference herein in its entirety.

### TECHNICAL FIELD

The present inventive concept relates to an integrated circuit (IC) device, and more particularly, to an IC device including a field-effect transistor (FET).

### DISCUSSION OF THE RELATED ART

As the downscaling of IC devices has progressed rapidly, increased operation speeds as well as increased operation accuracy are desirable in IC devices. Accordingly, various studies are being conducted to provide IC devices having structures that are capable of providing increased performance and increased reliability.

### SUMMARY

According to an embodiments of the present inventive concept, an integrated circuit device includes: a fin-type active region extending lengthwise in a first direction on a substrate; a nanosheet disposed on the fin-type active region; a gate line surrounding the nanosheet on the fin-type active region, wherein the gate line overlaps the nanosheet in a vertical direction; a source/drain region disposed on the fin-type active region, wherein the source/drain region contacts the nanosheet; and an interface insulating film surrounding the gate line, wherein the interface insulating film includes an inner spacer portion disposed between a sidewall of the gate line and the source/drain region, wherein the inner spacer portion of the interface insulating film includes: a first inner spacer portion protruding toward the source/drain region, while covering the sidewall of the gate line and while spaced apart from the nanosheet, wherein the first inner spacer portion has a first thickness in the first direction; and a second inner spacer portion extending from the first inner spacer portion toward the nanosheet and contacting the nanosheet, wherein the second inner spacer portion has a second thickness in the first direction, wherein the second thickness is less than the first thickness.

According to an embodiments of the present inventive concept, an integrated circuit device includes: a fin-type active region extending lengthwise in a first direction on a substrate; a nanosheet stack facing a fin top surface of the fin-type active region, wherein the nanosheet stack includes a plurality of nanosheets at different vertical distances apart from the fin top surface of the fin-type active region; a gate line surrounding the plurality of nanosheets on the fin-type active region, and extending in a second direction, wherein the gate line includes a sub-gate portion disposed between two nanosheets adjacent to each other in a vertical direction, from among the plurality of nanosheets, wherein the second direction is substantially perpendicular to the first lateral direction; a pair of source/drain regions on both sides of the gate line on the fin- type active region, wherein the pair of source/drain regions contact the plurality of nanosheets; an interface insulating film surrounding the gate line; and a high-k dielectric film disposed between the gate line and the interface insulating film, wherein the interface insulating film includes a pair of inner spacer portions covering both sidewalls of the sub-gate portion between the pair of source/drain regions, wherein each of the pair of inner spacer portions of the interface insulating film includes: a first inner spacer portion protruding toward one of the pair of source/drain regions, while covering the sidewall of the sub-gate portion and while spaced apart from the plurality of nanosheets, wherein the first inner spacer has a first thickness in the first lateral direction; and a second inner spacer portion extending from the first inner spacer portion toward a selected one of the plurality of nanosheets and contacting the one nanosheet, wherein the second inner spacer portion has a second thickness in the first direction, wherein the second thickness is less than the first thickness.

According to an embodiments of the present inventive concept, an integrated circuit device includes: a fin-type active region extending lengthwise in a first direction on a substrate; a pair of nanosheets disposed on the fin-type active region, wherein the pair of nanosheets are spaced apart from each other; a gate line surrounding the pair of nanosheets on the fin-type active region and extending lengthwise in a second direction, wherein the gate line includes a sub-gate portion between the pair of nanosheets, wherein the second direction is substantially perpendicular to the first direction; a source/drain region disposed on the fin-type active region, wherein the source/drain region contacts the pair of nanosheets; an interface insulating film surrounding the gate line; and a high-k dielectric film disposed between the gate line and the interface insulating film, wherein the interface insulating film includes an inner spacer portion disposed between a sidewall of the sub-gate portion and the source/drain region, wherein the inner spacer portion of the interface insulating film includes: a first inner spacer portion protruding toward the source/drain region, while covering the sidewall of the sub-gate portion and while spaced apart from the pair of nanosheets, wherein the first inner spacer portion has a first thickness in the first lateral direction; and a second inner spacer portion extending from the first inner spacer portion toward a selected one of the pair of nanosheets and contacting the one nanosheet, wherein the second inner spacer portion has a second thickness in the first direction, wherein the second thickness is less than the first thickness, wherein a height of the first inner spacer portion in the vertical direction is greater than or equal to a height of the second inner spacer portion, and the first inner spacer portion protrudes by about 0.5 nm to about 4 nm beyond the second inner spacer portion in a direction away from the sub-gate portion in the first direction.

### BRIEF DESCRIPTION OF THE DRAWINGS

The above and other aspects of the present inventive concept will become more apparent by describing in detail embodiments thereof, with reference to the accompanying drawings, in which:

FIG. 1 is a plan layout diagram of an integrated circuit (IC) device according to embodiments of the present inventive concept;

FIG. 2A is a cross-sectional view taken along line X1-X1′ of FIG. 1;

FIG. 2B is a cross-sectional view taken along line Y1-Y1′ of FIG. 1;

FIG. 2C is a cross-sectional view taken along line Y2-Y2′ of FIG. 1;

FIG. 3A is an enlarged cross-sectional view of region “EX1” of FIG. 2A;

FIG. 3B is an enlarged cross-sectional view of region “EX1A” of FIG. 3A;

FIGS. 4, 5, and 6 are respectively enlarged cross-sectional views of IC devices according to embodiments of the present inventive concept, each illustrating a portion corresponding to portion “EX1A” of FIG. 3A;

FIG. 7 is a plan layout diagram of an IC device according to embodiments of the present inventive concept;

FIG. 8A is a cross-sectional view taken along line X1-X1′ of FIG. 7;

FIG. 8B is a cross-sectional view taken along line Y1-Y1′ of FIG. 7;

FIG. 8C is a cross-sectional view taken along line Y2-Y2′ of FIG. 7;

FIGS. 9A, 9B, 10A, 10B, 11, 12, 13, 14, 15A, 15B, 16, 17A, 17B, 18A, and 18B are cross-sectional views of a process sequence of a method of manufacturing an IC device, according to embodiments of the present inventive concept. FIGS. 9A, 10A, 11, 12, 13, 14, 15A, 16, 17A, and 18A are cross-sectional views of some components in a portion corresponding to a cross-section taken along line X1-X1′ of FIG. 1, according to a process sequence. FIGS. 9B, 10B, 15B, 17B, and 18B are cross-sectional views of some components in a portion corresponding to a cross-section taken along line Y1-Y1′ of FIG. 1, according to a process sequence;

FIGS. 19, 20, and 21 are cross-sectional views of some components in a portion corresponding to a cross-section taken along line X1-X1′ of FIG. 1, illustrating a process sequence of a method of manufacturing an IC device, according to embodiments of the present inventive concept; and

FIGS. 22A, 22B, 23A, 23B, 24A, 24B, 25A, 25B, 25C, 26A, 26B, 27A, 27B, 28A, 28B, 29A, 29B, 29C, 30A, 30B, 30C, 31A, 31B, 31C, 32A, 32B, 33A, and 33B are cross-sectional views of a process sequence of a method of manufacturing an IC device, according to embodiments of the present inventive concept. FIGS. 22A, 23A, 24A, 25A, 26A, 27A, 28A, 29A, 30A, 31A, 32A, and 33A are cross-sectional views of example structures of a portion corresponding to a cross-section taken along line X1-X1′ of FIG. 7, according to a process sequence. FIGS. 22B, 23B, 24B, 25B, 26B, 29B, 30B, 31B, 32B, and 33B are cross-sectional views of example structures of a portion corresponding to a cross-section taken along line Y1-Y1′ of FIG. 7, according to a process sequence. FIGS. 25C, 27B, 28B, 29C, 30C, and 31C are cross-sectional views of example structures of a portion corresponding to a cross-section taken along line Y2-Y2′ of FIG. 7, according to a process sequence.

### DETAILED DESCRIPTION OF THE EMBODIMENTS

Hereinafter, embodiments of the present inventive concept will be described in detail with reference to the accompanying drawings. The same reference numerals are used to denote the same elements in the drawings, and repeated descriptions thereof are omitted or briefly discussed.

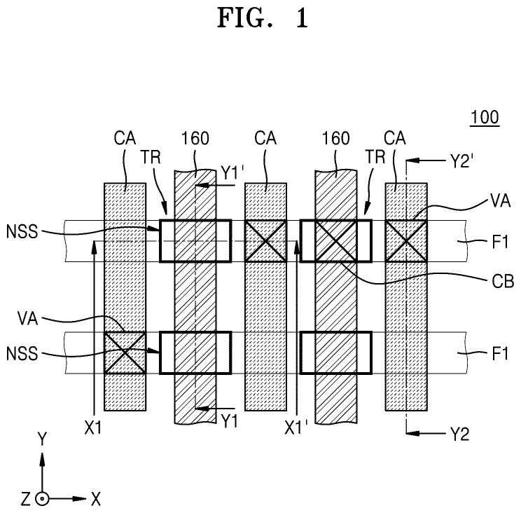

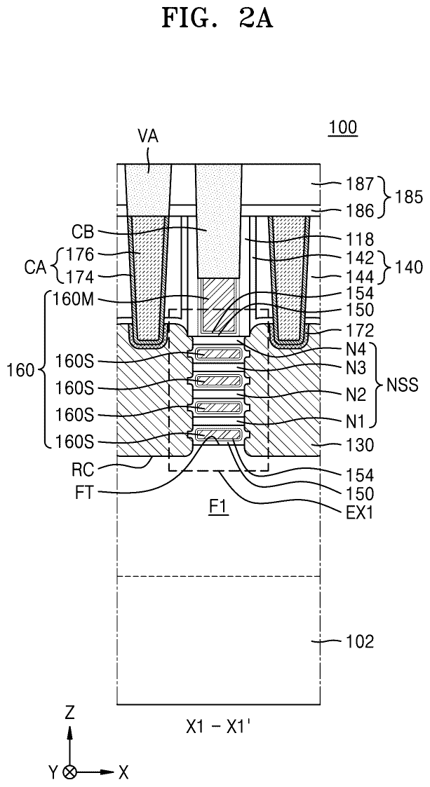

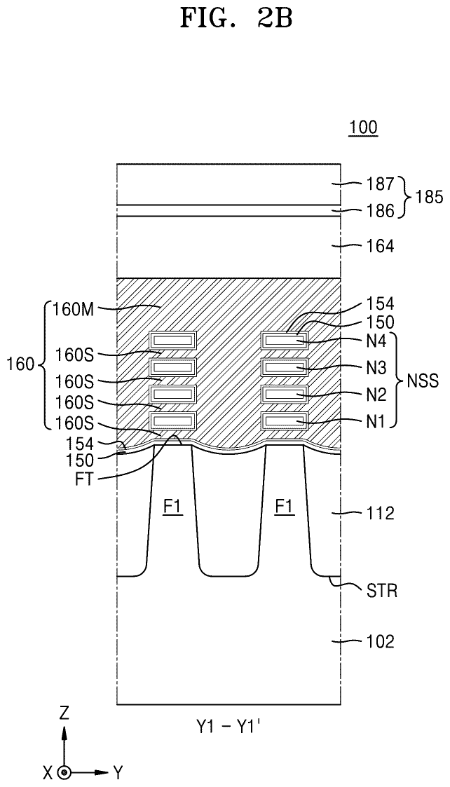

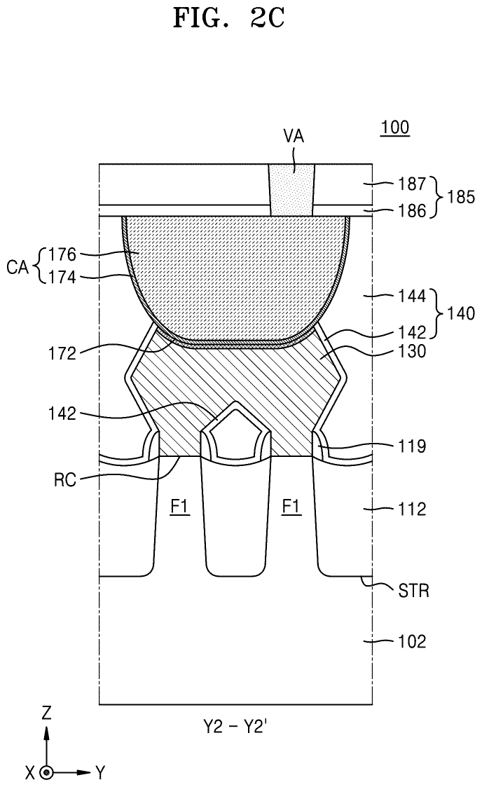

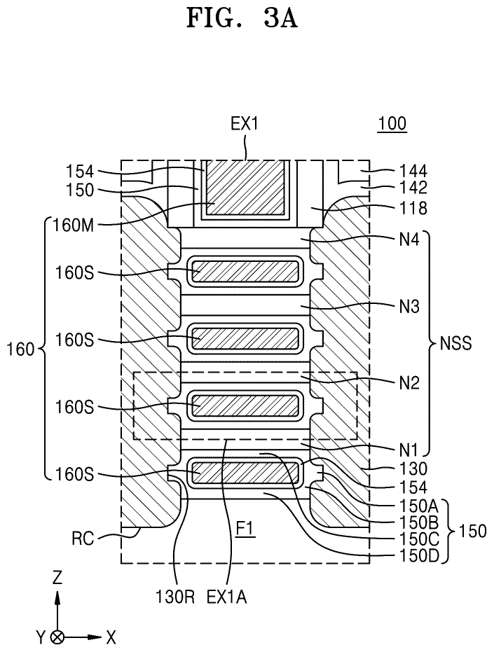

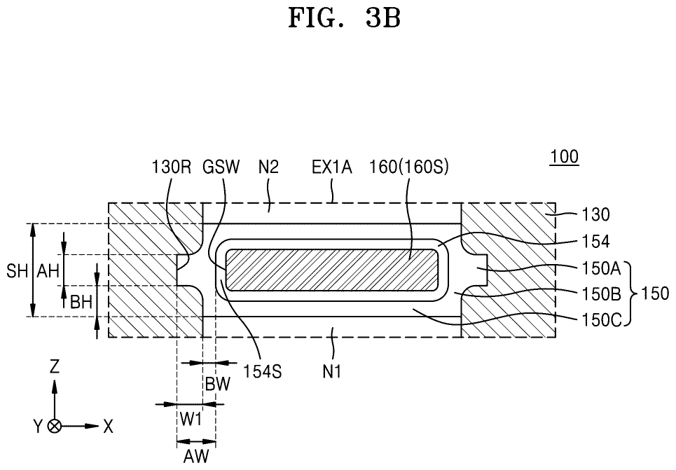

FIG. 1 is a plan layout diagram of an integrated circuit (IC) device 100 according to embodiments of the present inventive concept. FIG. 2A is a cross-sectional view taken along line X1-X1′ of FIG. 1. FIG. 2B is a cross-sectional view taken along line Y1-Y1′ of FIG. 1. FIG. 2C is a cross-sectional view taken along line Y2-Y2′ of FIG. 1. FIG. 3A is an enlarged cross- sectional view of region “EX1” of FIG. 2A. FIG. 3B is an enlarged cross-sectional view of region “EX1A” of FIG. 3A. The IC device 100 including a field-effect transistor (FET) having a gate-all-around structure including an active region of a nanowire or nanosheet type and a gate surrounding the active region will now be described with reference to FIGS. 1, 2A to 2C, 3A, and 3B.

Referring to FIGS. 1, 2A to 2C, 3A, and 3B, the IC device 100 may include a plurality of fin-type active regions F1 and a plurality of nanosheet stacks NSS. The plurality of fin-type active regions F1 may protrude from a substrate 102 and extend lengthwise in a first lateral direction (X direction). The plurality of nanosheet stacks NSS may be spaced apart upward from the plurality of fin-type active regions F1 in a vertical direction (Z direction) and face a fin top surface FT of the fin-type active region F1. As used herein, the term “nanosheet” refers to a conductive structure having a cross-section that is substantially perpendicular to a direction in which current flows. The nanosheet may be interpreted as including a nanowire. The substrate 102 may include a semiconductor, such as silicon (Si) or germanium (Ge), or a compound semiconductor, such as silicon germanium (SiGe), silicon carbide (SiC), gallium arsenide (GaAs), indium arsenide (InAs), indium gallium arsenide (InGaAs), or indium phosphide (InP). As used herein, each of the terms SiGe, SiC, GaAs, InAs, InGaAs, and InP refers to a material including elements included therein, without referring to a chemical formula representing a stoichiometric relationship. The substrate 102 may include a conductive region, for example, a doped well or a doped structure.

A device isolation trench STR defining the plurality of fin-type active regions F1 may be formed in the substrate 102. The device isolation trench STR may be filled by a field insulating film 112 that is disposed between a pair of fin-type active regions F1, which are adjacent to each other in a second lateral direction (Y direction) that is perpendicular to the first lateral direction, from among the plurality of fin-type active regions F1. The field isolation film 112 may include a silicon oxide film. A plurality of gate lines 160 may be disposed on the plurality of fin-type active regions F1. Each of the plurality of gate lines 160 may extend lengthwise in a second lateral direction (Y direction). A plurality of nanosheet stacks NSS may be respectively disposed on fin top surfaces FT of the plurality of fin-type active regions F1 in regions where the plurality of fin-type active regions F1 intersect the plurality of gate lines 160. The plurality of nanosheet stacks NSS may include at least one nanosheet. As shown in FIGS. 2A and 2B, each of the plurality of nanosheet stacks NSS may include first to fourth nanosheets N1, N2, N3, and N4, which overlap each other on the fin-type active region F1 in the vertical direction (Z direction). Each of the first to fourth nanosheets N1, N2, N3, and N4 included in the nanosheet stack NSS may provide a channel region. In embodiments of the present inventive concept, each of the first to fourth nanosheets N1, N2, N3, and N4 in the nanosheet stack NSS may include a silicon (Si) layer, a silicon germanium (SiGe) layer, or a combination thereof. For example, each of the first to fourth nanosheets N1, N2, N3, and N4 may include a silicon (Si) layer.

The first to fourth nanosheets N1, N2, N3, and N4 may be disposed at different vertical distances (Z-directional distances) from the fin top surface FT of the fin-type active region F1. For example, the first to fourth nanosheets N1, N2, N3, and N4 may be disposed at different vertical distances (Z-directional distances) from each other with respect to the fin top surface FT of the fin-type active region F1. Each of the plurality of gate lines 160 may surround the first to fourth nanosheets N1, N2, N3, and N4, which overlap each other in the vertical direction (Z direction) and are in the nanosheet stack NSS.

Although FIG. 1 illustrates a case in which the nanosheet stack NSS has a substantially rectangular planar shape, the present inventive concept is not limited thereto. The nanosheet stack NSS may have various planar shapes according to a planar shape of each of the fin-type active region F1 and the gate line 160. The present embodiment pertains to a configuration in which the plurality of nanosheet stacks NSS and the plurality of gate lines 160 are formed on one fin-type active region F1, and the plurality of nanosheet stacks NSS are arranged in a line in the first lateral direction (X direction) on one fin-type active region F1. However, the number of nanosheet stacks NSS and the number of gate lines 160 on one fin-type active region F1 are not specifically limited.

For example, each of the first to fourth nanosheets N1, N2, N3, and N4 may have a thickness selected from a range of about 4 nm to about 6 nm, without being limited thereto. Here, the thickness of each of the first to fourth nanosheets N1, N2, N3, and N4 refers to a size of each of the first to third nanosheets N1, N2, N3, and N4 in the vertical direction (Z direction). In embodiments of the present inventive concept, the first to fourth nanosheets N1, N2, N3, and N4 may have substantially the same thickness as each other in the vertical direction (Z direction). In embodiments of the present inventive concept, at least some of the first to fourth nanosheets N1, N2, N3, and N4 may have different thicknesses from each other in the vertical direction (Z direction).

As shown in FIG. 2A, the first to fourth nanosheets N1, N2, N3, and N4 included in one nanosheet stack NSS may have the same size or similar sizes as each other in the first lateral direction (X direction). In embodiments of the present inventive concept, differently from that shown in FIG. 2A, at least some of the first to fourth nanosheets N1, N2, N3, and N4 included in one nanosheet stack NSS may have different sizes from each other in the first lateral direction (X direction).

The present embodiment illustrated in FIGS. 2A and 2B pertains to an example in which each of the plurality of nanosheet stacks NSS includes four nanosheets including the first to fourth nanosheets N1, N2, N3, and N4, but the present inventive concept is not limited thereto. For example, the nanosheet stack NSS may include at least one nanosheet, and the number of nanosheets in the nanosheet stack NSS is not specifically limited.

As shown in FIGS. 2A and 2B, each of the plurality of gate lines 160 may include a main gate portion 160M and a plurality of sub-gate portions 160S. The main gate portion 160M may cover a top surface of the nanosheet stack NSS and extend in the second lateral direction (Y direction). For example, the main gate portion 160M may be disposed on the top surface of the nanosheet stack NSS. The plurality of sub-gate portions 160S may be integrally connected to the main gate portion 160M and may be respectively arranged one-by-one between the first to fourth nanosheets N1, N2, N3, and N4 and between the first nanosheet N1 and the fin top surface FT of the fin-type active region F1. In the vertical direction (Z direction), a thickness of each of the plurality of sub-gate portions 160S may be less than a thickness of the main gate portion 160M.

Each of the gate lines 160 may include, for example, a metal, a metal nitride, a metal carbide, or a combination thereof. The metal may be at least one of, for example, molybdenum (Mo), ruthenium (Ru), copper (Cu), and tungsten (W). The metal nitride may be selected from titanium nitride (TiN), tantalum nitride (TaN), titanium aluminum nitride (TiAlN), or a combination thereof. The metal carbide may include, for example, titanium aluminum carbide (TiAlC). However, a material included in the plurality of gate lines 160 is not limited to the examples described above.

As shown in FIG. 2B, the field insulating film 112 may be disposed between the substrate 102 and the gate line 160 in the vertical direction (Z direction). The field insulating film 112 may cover respective sidewalls of a pair of fin-type active regions F1, which are adjacent to each other, on both sides of the field insulating film 112 in the second lateral direction (Y direction).

An interface insulating film 150 and a high-k dielectric film 154 may be between the nanosheet stack NSS and the gate line 160. The interface insulating film 150 and the high-k dielectric film 154 may at least partially surround the gate line 160. A relative thickness of each of the interface insulating film 150 and the high-k dielectric film 154 is not limited to those illustrated in FIGS. 2A, 2B, 3A, and 3B. When necessary, the IC device 100 may include at least one of a portion in which a thickness of the interface insulating film 150 is greater than a thickness of the high-k dielectric film 154, a portion in which the thickness of the interface insulating film 150 is less than the thickness of the high-k dielectric film 154, and/or a portion in which the thickness of the interface insulating film 150 is substantially equal to the thickness of the high-k dielectric film 154.

As shown in FIG. 2B, in a cross-section taken in the second lateral direction (Y direction), the interface insulating film 150 and the high-k dielectric film 154 may at least partially surround each of the first to fourth nanosheets N1, N2, N3, and N4 without being cut off between the gate line 160 and each of the first to fourth nanosheets N1, N2, N3, and N4.

In embodiments of the present inventive concept, the interface insulating film 150 may include a low-k dielectric material film e.g., a silicon oxide film, a silicon oxynitride film, or a combination thereof, which has a dielectric constant of about 9 or less. For example, the interface insulating film 150 may include a silicon oxide film. In embodiments of the present inventive concept, the high-k dielectric film 154 may include a material having a higher dielectric constant than that of a silicon oxide film. For example, the high-k dielectric film may have a dielectric constant of about 10 to 25. The high-k dielectric film may include hafnium oxide, without being limited thereto.

The interface insulating film 150 may contact a surface of each of the plurality of fin-type active regions F1 and a surface of each of the first to fourth nanosheets N1, N2, N3, and N4 included in each of the plurality of nanosheet stacks NSS and surround each of the plurality of gate lines 160. The high-k dielectric film 154 may be between the interface insulating film 150 and the gate line 160. For example, the high-k dielectric film 154 may contact a bottom surface and both sidewalls of the gate line 160.

As shown in FIGS. 2A and 2C, a plurality of recesses RC may be formed in the fin-type active region F1. A lowermost surface of each of the plurality of recesses RC may be at a lower vertical level than the fin top surface FT of the fin-type active region F1. As used herein, the term “vertical level” refers to a distance from a main surface of the substrate 102 in the vertical direction (Z direction or −Z direction).

A plurality of source/drain regions 130 may be disposed inside the plurality of recesses RC. Each of the plurality of source/drain regions 130 may be adjacent to at least one gate line 160 selected from the plurality of gate lines 160. Each of the plurality of source/drain regions 130 may have surfaces contacting the first to fourth nanosheets N1, N2, N3, and N4 included in the nanosheet stack NSS adjacent thereto.

Each of the plurality of source/drain regions 130 may include an epitaxially grown semiconductor layer. In embodiments of the present inventive concept, each of the plurality of source/drain regions 130 may include an epitaxially grown Si layer, an epitaxially grown SiC layer, or a plurality of epitaxially grown SiGe layers. When the source/drain region 130 constitutes an NMOS transistor, the source/drain region 130 may include a Si layer doped with an n-type dopant or a SiC layer doped with an n-type dopant. The n-type dopant may be at least one of, for example, phosphorus (P), arsenic (As), and antimony (Sb). When the source/drain region 130 constitutes a PMOS transistor, the source/drain region 130 may include a SiGe film doped with a p-type dopant. The p-type dopant may be at least one of, for example, boron (B) and gallium (Ga).

As shown in FIG. 2A, both sidewalls of each of the plurality of sub-gate portions 160S included in the gate line 160 may be spaced apart from the source/drain region 130 with the interface insulating film 150 and the high-k dielectric film 154 therebetween. Each of the interface insulating film 150 and the high-k dielectric film 154 may include portions that are interposed between the sub-gate portion 160S included in the gate line 160 and each of the first to fourth nanosheets N1, N2, N3, and N4 and between the sub-gate portion 160S included in the gate line 160 and the source/drain region 130.

As shown in FIGS. 2A, 3A, and 3B, the interface insulating film 150 may include a plurality of first inner spacer portions 150A, a plurality of second inner spacer portions 150B, a plurality of first gate insulating portions 150C, and a plurality of second gate insulating portions 150D, which are integrally connected to each other.

In the interface insulating film 150, the first inner spacer portion 150A and the second inner spacer portion 150B may be portions between a sidewall of the sub-gate portion 160S of the gate line 160 and the source/drain region 130. As used herein, the first inner spacer portion 150A and the second inner spacer portion 150B may be referred to as an inner spacer.

In the interface insulating film 150, the second gate insulating portion 150D may be a portion, which is between the first nanosheet N1 closest to the fin-type active region F1, from among the first to fourth nanosheets N1, N2, N3, and N4 included in the nanosheet stack NSS, and the fin-type active region F1 and contacts the fin-type active region F1. In the interface insulating film 150, the first gate insulating portion 150C may be a portion between the sub-gate portion 160S of the gate line 160 and any one of the first to fourth nanosheets N1, N2, N3, and N4 included in the nanosheet stack NSS. As used herein, the first gate insulating portion 150C and the plurality of second gate insulating portions 150D may be referred to as a gate insulating portion.

In the interface insulating film 150, the first inner spacer portion 150A may be spaced apart from each of the first to fourth nanosheets N1, N2, N3, and N4 and protrude toward the source/drain region 130, while covering a sidewall GSW facing the source/drain region 130, of the sub-gate portion 160S of the gate line 160. In the interface insulating film 150, the second inner spacer portion 150B may extend from the first inner spacer portion 150A toward one nanosheet adjacent thereto, from among the first to fourth nanosheets N1, N2, N3, and N4, and contact the adjacent one nanosheet. The second inner spacer portion 150B may fill a corner space that is defined by any one of the first to fourth nanosheets N1, N2, N3, and N4 and the source/drain region 130 in a portion where the one nanosheet meets the source/drain region 130. For example, the corner space may be defined by a corner of a corresponding nanosheet of the first to fourth nanosheets N1, N2, N3 and N4 and a corner of the source/drain region 130 that is adjacent to the corresponding nanosheet, and the corner of the corresponding nanosheet faces the corner of the source/drain region 130.

In the interface insulating film 150, the first inner spacer portion 150A may have a first thickness AW in the first lateral direction (X direction), and the second inner spacer portion 150B may have a second thickness BW that is less than the first thickness AW in the first lateral direction (X direction). In embodiments of the present inventive concept, the first thickness AW may be selected from a range of about 1.5 nm to about 5 nm, without being limited thereto. The second thickness BW may be less than the first thickness AW and have a value selected from a range of about 1 nm to about 3 nm, without being limited thereto.

As shown in FIG. 3B, the first inner spacer portion 150A may protrude by a protrusion width W1 beyond the second inner spacer portion 150B in a direction away from the sub-gate portion 160S of the gate line 160 in the first lateral direction (X direction). The protrusion width W1 of a portion of the first inner spacer portion 150A, which protrudes further than the second inner spacer portion 150B in the direction away from the sub-gate portion 160S, may be in a range of about 0.5 nm to about 4 nm (e.g., about 1 nm to about 3 nm), without being limited thereto.

As an example, each of the second inner spacer portion 150B, the first gate insulating portion 150C, and the plurality of second gate insulating portions 150D may a thickness of 1 nm in the interface insulating film 150, and a parasitic capacitance of an IC device was reduced while gradually increasing a protrusion width W1 of a portion of the first inner spacer portion 150A, which protrudes beyond the second inner spacer portion 150B in a direction away from the sub-gate portion 160S, from 1 nm to 3 nm. As a result, as the protrusion width W1 is increased, the parasitic capacitance of the IC device may be reduced.

In embodiments of the present inventive concept, in the vertical direction (Z direction), a height AH of the first inner spacer portion 150A of the interface insulating film 150 may be greater than or equal to a height BH of the second inner spacer portion 150B. In the vertical direction (Z direction), the height AH of the first inner spacer portion 150A of the interface insulating film 150 may be less than a separation distance SH between a pair of adjacent ones selected from the first to fourth nanosheets N1, N2, N3, and N4 in the vertical direction (Z direction). For example, the height AH of the first inner spacer portion 150A of the interface insulating film 150 may be less than the separation distance SH that is between a pair of nanosheets that are adjacent to the sub-gate portion 160S, which is adjacent to the first inner spacer portion 150A, in the vertical direction (Z direction) (i.e., the separation distance SH between a pair of adjacent nanosheets selected from the first to fourth nanosheets N1, N2, N3, and N4).

In embodiments of the present inventive concept, two nanosheets, which are selected from the first to fourth nanosheets N1, N2, N3, and N4 and are spaced apart from each other with the sub-gate portion 160S therebetween in the vertical direction (Z direction), may be the separation distance SH apart from each other in the vertical direction (Z direction). The height AH of the first inner spacer portion 150A in the vertical direction (Z direction) may be about 0.2 times or more the separation distance SH and less than the separation distance SH. For example, the height AH of the first inner spacer portion 150A in the vertical direction (Z direction) may be about 0.3 times to about 0.9 times the separation distance SH between two nanosheets, which are spaced apart from each other with the sub-gate portion 160S therebetween, in the vertical direction (Z direction).

The first thickness AW and the height AH of the interface insulating film 150 may be variously selected as needed. For example, the first thickness AW of the interface insulating film 150 may substantially be equal to the height AH of the interface insulating film 150, without being limited thereto.

In the vertical direction (Z direction), a thickness of each of the first gate insulating portion 150C of the interface insulating film 150 and the plurality of second gate insulating portions 150D may be less than the height AH of the first inner spacer portion 150A and less than the first thickness AW of the first inner spacer portion 150A. A thickness of each of the first gate insulating portion 150C of the interface insulating film 150 and the plurality of second gate insulating portions 150D may be less than or equal to the second thickness BW of the second inner spacer portion 150B.

In the IC device 100, the second inner spacer portion 150B of the interface insulating film 150 may fill a corner space defined by any one of the first to fourth nanosheets N1, N2, N3, and N4 and the source/drain region 130 by a relatively small thickness in a portion where the one nanosheet meets the source/drain region 130. Accordingly, problems, such as the formation of an undesired potential barrier near a portion of the source/drain region 130, which is adjacent to the first nanosheet N1, the second nanosheet N2, the third nanosheet N3, or the fourth nanosheet N4, or the formation of a depletion region through which carriers cannot pass at a channel entrance, may be prevented.

The high-k dielectric film 154 may include a high-k dielectric film side portion 154S between the first inner spacer portion 150A and the sub-gate portion 160S of the gate line 160 and between the second inner spacer portion 150B and the sub-gate portion 160S of the gate line 160, and a thickness of the high-k dielectric film side portion 154S in the first lateral direction (X direction) may be less than the first thickness AW.

As shown in FIGS. 2A, 3A, and 3B, the source/drain region 130 may include a side recess portion 130R that accommodates the first inner spacer portion 150A of the interface insulating film 150. The side recess portion 130R of the source/drain region 130 may be indented from surfaces of the source/drain region 130, which are respectively in contact with the first to fourth nanosheets N1, N2, N3, and N4, in a direction away from the sub-gate portion 160S in the first lateral direction (X direction).

As shown in FIG. 2B, a top surface of each of the gate lines 160 may be covered by a capping insulating pattern 164. The capping insulating pattern 164 may include, for example, a silicon nitride film. As shown in FIG. 2A, both sidewalls of the gate line 160 in the first lateral direction (X direction) may be covered by a pair of first insulating spacers 118. Each of a plurality of first insulating spacers 118 in the IC device 100 may extend lengthwise along with the gate line 160 in the second lateral direction (Y direction) on the nanosheet stack NSS and the field insulating film 112. The first insulating spacers 118 may cover the both sidewalls of the main gate portion 160M on top surfaces of the plurality of nanosheet stacks NSS. The first insulating spacer 118 may be spaced apart from the gate line 160 with the interface insulating film 150 and the high-k dielectric film 154 therebetween. The first insulating spacer 118 may include, for example, silicon nitride, silicon oxide, silicon carbonitride (SiCN), silicon boron nitride (SiBN), silicon oxynitride (SiON), silicon oxycarbonitride (SiOCN), silicon boron carbonitride (SiBCN), silicon oxycarbide (SiOC), or a combination thereof. As used herein, each of the terms “SiCN,” “SiBN,” “SiON,” “SiOCN,” “SiBCN,” and “SiOC” refers to a material including elements included therein, without referring to a chemical formula representing a stoichiometric relationship.

The interface insulating film 150 and the high-k dielectric film 154 may cover a surface of the fin-type active region F1 and a surface of each of the first to fourth nanosheets N1, N2, N3, and N4 included in the nanosheet stack NSS in a space that is defined by the pair of first insulating spacers 118. The interface insulating film 150 and the high-k dielectric film 154 may cover the bottom surface and the both sidewalls of the gate line 160. For example, the high-k dielectric film 154 may contact the bottom surface and the both sidewalls of the gate line 160, and the interface insulating film 150 may be spaced apart from the gate line 160 with the high-k dielectric film 154 therebetween.

The plurality of nanosheet stacks NSS may be respectively on the fin top surfaces FT of the plurality of fin-type active regions F1 in regions where the plurality of fin-type active regions F1 intersect the plurality of gate lines 160, and a plurality of FETs TR may be formed at intersections between the plurality of fin-type active regions F1 and the plurality of gate lines 160 on the substrate 102.

A metal silicide film 172 may be disposed on a top surface of each of the plurality of source/drain regions 130. The metal silicide film 172 may include a metal, which includes at least one of, for example, titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and/or palladium (Pd). For example, the metal silicide film 172 may include titanium silicide, without being limited thereto.

An insulating liner 142 and an inter-gate dielectric film 144 may be sequentially disposed on the plurality of source/drain regions 130 and a plurality of metal silicide films 172. The insulating liner 142 and the inter-gate dielectric film 144 may constitute an inter-gate dielectric structure 140. The first insulating spacer 118 and the plurality of source/drain regions 130 may be covered by the insulating liner 142. In embodiments of the present inventive concept, the insulating liner 142 may include silicon nitride (SIN), SiCN, SiBN, SION, SiOCN, SiBCN, or a combination thereof, without being limited thereto. The inter-gate dielectric film 144 may include, for example, a silicon oxide film, without being limited thereto.

As shown in FIG. 2C, the field insulating film 112 may have a top surface contacting the insulating liner 142 of the inter-gate dielectric structure 140. A plurality of second insulating spacers 119 may be on the field insulating film 112 on both sides of the source/drain region 130 in the second lateral direction (Y direction). Each of the plurality of second insulating spacers 119 may cover a sidewall of a partial region of the source/drain region 130, which is adjacent to the fin-type active region F1. Each of the plurality of second insulating spacers 119 may contact a sidewall of the source/drain region 130. The plurality of second insulating spacers 119 may be covered by the inter-gate dielectric structure 140. Each of the plurality of source/drain regions 130 and the plurality of second insulating spacers 119 may be disposed on the insulating liner 142 that is included in the inter-gate dielectric structure 140. For example, each of the plurality of source/drain regions 130 and the plurality of second insulating spacers 119 may have a surface contacting the insulating liner 142 that is included in the inter-gate dielectric structure 140. Each of the plurality of second insulating spacers 119 may include the same material as a constituent material of the first insulating spacer 118. In embodiments of the present inventive concept, at least portions of the plurality of second insulating spacers 119 may be omitted.

As shown in FIGS. 2A and 2C, a plurality of source/drain contacts CA may be on the plurality of source/drain regions 130. Each of the plurality of source/drain contacts CA may pass through the inter-gate dielectric structure 140, which includes the inter-gate dielectric film 144 and the insulating liner 142 in the vertical direction (Z direction) and be electrically connected to at least one source/drain region 130 selected from the plurality of source/drain regions 130. Each of the plurality of source/drain contacts CA may contact the metal silicide film 172 that is formed on the source/drain region 130. Each of the plurality of source/drain contacts CA may be electrically connectable to the source/drain region 130 through the metal silicide film 172. Each of the plurality of source/drain contacts CA may be spaced apart from the metal gate portion 160M of the gate line 160 with the first insulating spacer 118 therebetween in the first lateral direction (X direction).

Each of the plurality of source/drain contacts CA may include a conductive barrier film 174 and a metal plug 176. A bottom surface and a sidewall of the metal plug 176 may be covered by the conductive barrier film 174. The conductive barrier film 174 may include a metal or a conductive metal nitride. For example, the conductive barrier film 174 may include titanium (Ti), tantalum (Ta), tungsten (W), titanium nitride (TiN), tantalum nitride (TaN), tungsten nitride (WN), tungsten carbonitride (WCN), titanium silicon nitride (TiSiN), tantalum silicon nitride (TaSiN), tungsten silicon nitride (WSiN), or a combination thereof, without being limited thereto. The metal plug 176 may include molybdenum (Mo), tungsten (W), cobalt (Co), ruthenium (Ru), manganese (Mn), titanium (Ti), tantalum (Ta), aluminum (Al), copper (Cu), a combination thereof, or an ally thereof, without being limited thereto. In embodiments of the present inventive concept, the conductive barrier film 174 may be omitted in each of the plurality of source/drain contacts CA.

A top surface of each of the source/drain contact CA, the capping insulating pattern 164, and the inter-gate dielectric structure 140 may be covered by an upper insulating structure 185. The upper insulating structure 185 may include an etch stop film 186 and an upper insulating film 187, which are sequentially stacked on each of the plurality of source/drain contacts CA, a plurality of capping insulating patterns 164, and the inter-gate dielectric structure 140. The etch stop film 186 may include, for example, silicon carbide (SiC), SiN, SiCN, SiOC, AlN, AlON, AlO, AlOC, or a combination thereof. The upper insulating film 187 may include, for example, an oxide film, a nitride film, an ultralow-k (ULK) film having an ultralow dielectric constant K of about 2.2 to about 2.4, or a combination thereof. For example, the upper insulating film 187 may include, for example, a tetraethylorthosilicate (TEOS) film, a high-density plasma (HDP) film, a boro-phospho-silicate glass (BPSG) film, a flowable chemical vapor deposition (FCVD) oxide film, a silicon oxynitride (SiON) film, a silicon nitride (SiN) film, a silicon oxycarbide (SiOC) film, a SiCOH film, or a combination thereof, without being limited thereto.

As shown in FIGS. 2A and 2C, a source/drain via contact VA may be disposed on the source/drain contact CA. Each of a plurality of source/drain via contacts VA may pass through the upper insulating structure 185 and contact the source/drain contact CA. From among the plurality of source/drain regions 130, the source/drain region 130 connected to the source/drain contact CA may be electrically connected to the source/drain via contact VA through the metal silicide film 172 and the source/drain contact CA. Each of the plurality of source/drain via contacts VA may include, for example, molybdenum (Mo) or tungsten (W), without being limited thereto.

As shown in FIG. 2A, a gate contact CB may be on the gate line 160. The gate contact CB may pass through the upper insulating structure 185 and the capping insulating pattern 164 in the vertical direction (Z direction) and be connected to the gate line 160. A bottom surface of the gate contact CB may be in contact with a top surface of the gate line 160. The gate contact CB may include a contact plug, which includes, for example, molybdenum (Mo), copper (Cu), tungsten (W), cobalt (Co), ruthenium (Ru), manganese (Mn), titanium (Ti), tantalum (Ta), aluminum (Al), a combination thereof, or an ally thereof. In embodiments of the present inventive concept, the gate contact CB may further include a conductive barrier pattern surrounding a portion of the contact plug. The conductive barrier pattern included in the gate contact CB may include a metal or a metal nitride. For example, the conductive barrier pattern may include Ti, Ta, W, TiN, TaN, WN, WCN, TiSiN, TaSiN, WSiN, or a combination thereof.

The IC device 100 described with reference to FIGS. 1, 2A to 2C, 3A, and 3B may include the interface insulating film 150 surrounding the gate line 160, and the interface insulating film 150 may include an inner spacer portion between a sidewall of the sub-gate portion 160S of the gate line 160 and the source/drain region 130. The inner spacer portion of the interface insulating film 150 may include the first inner spacer portion 150A and the second inner spacer portion 150B. The first inner spacer portion 150A may be spaced apart from the first nanosheet N1, the second nanosheet N2, the third nanosheet N3, or the fourth nanosheet N4 included in the nanosheet stack NSS and locally protrude toward the source/drain region 130, while covering the sidewall of the sub-gate portion 160S. The second inner spacer portion 150B may extend from the first inner spacer portion 150A toward one nanosheet adjacent thereto, from among the first to fourth nanosheets N1, N2, N3, and N4, and contact the adjacent nanosheet. The first inner spacer portion 150A may have such a relatively large thickness as to provide a sufficient insulation distance between the sub-gate portion 160S and the source/drain region 130. Because the second inner spacer portion 150B has a thickness less than the thickness of the first inner spacer portion 150A, problems, such as the formation of an undesired potential barrier near a portion of the source/drain region 130, which is adjacent to the first nanosheet N1, the second nanosheet N2, the third nanosheet N3, or the fourth nanosheet N4, or the formation of a depletion region through which carriers cannot pass at a channel entrance, may be prevented. Accordingly, in the present inventive concept, even when the IC device 100 has a device region with a reduced area with the downscaling trend, undesired parasitic capacitance and leakage current, which may occur between the source/drain region 130 and the sub-gate portion 160S of the gate line 160 surrounding the first to fourth nanosheets N1, N2, N3, and N4 that provide the channel region, may be minimized, and gate controllability and current drivability may improve. Therefore, in the IC device 100 according to the present inventive concept, the performance and reliability of an FET including a plurality of nanosheets (e.g., the first to fourth nanosheets N1, N2, N3, and N4) may increase.

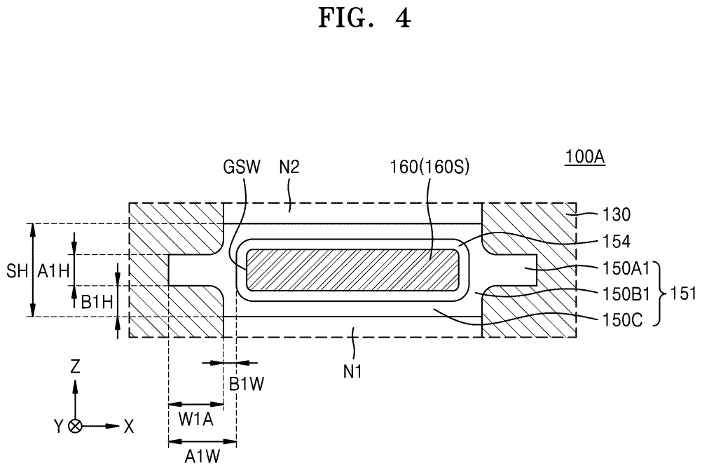

FIGS. 4 to 6 are respectively cross-sectional views of IC devices 100A, 100B, and 100C according to embodiments of the present inventive concept. FIGS. 4 to 6 each illustrate an enlarged cross-sectional configuration of a portion corresponding to portion “EX1A” of FIG. 3A. In FIGS. 4 to 6, the same reference numerals are used to denote the same elements as in FIGS. 1, 2A to 2C, 3A, and 3B, and thus, detailed descriptions thereof are omitted.

Each of the IC devices 100A, 100B, and 100C described with reference to FIGS. 4 to 6 may substantially have the same configuration as the IC device 100 described with reference to FIGS. 1, 2A to 2C, 3A, and 3B. However, unlike the IC device 100 described with reference to FIGS. 1, 2A to 2C, 3A, and 3B, the IC devices 100A, 100B, and 100C shown in FIGS. 4 to 6 may have configurations that are described below.

Referring to FIG. 4, the IC device 100A may include an interface insulating film 151 and a high-k dielectric film 154 between the nanosheet stack NSS and a gate line 160. The interface insulating film 151 may substantially have the same configuration as the interface insulating film 150, which has been described with reference to FIGS. 2A, 2B, 3A, and 3B. However, the interface insulating film 151 may include a first inner spacer portion 150A1 and a second inner spacer portion 150B1, which are disposed between a sidewall GSW of a sub-gate portion 160S of the gate line 160 and the source/drain region 130. The first inner spacer portion 150A1 and the second inner spacer portion 150B1 may constitute an inner spacer portion.

In the interface insulating film 151, the first inner spacer portion 150A1 may be spaced apart from each of first to fourth nanosheets N1, N2, N3, and N4 and protrude toward the source/drain region 130, while covering the sidewall GSW, which faces the source/drain region 130, of the sub-gate portion 160S of the gate line 160. In the interface insulating film 151, the second inner spacer portion 150B1 may extend from the first inner spacer portion 150A1 toward one nanosheet adjacent thereto, from among the first to fourth nanosheets N1, N2, N3, and N4, and contact the adjacent one nanosheet.

In the interface insulating film 151, the first inner spacer portion 150A1 may have a first thickness A1W in a first lateral direction (X direction), and the second inner spacer portion 150B1 may have a second thickness B1W that is less than the first thickness A1W in the first lateral direction (X direction). In embodiments of the present inventive concept, the first thickness A1W may be selected from a range of about 1.5 nm to about 8 nm, without being limited thereto. The second thickness B1W may be less than the first thickness A1W and be selected from a range of about 1 nm to about 3 nm, without being limited thereto.

The first inner spacer portion 150A1 may protrude by a protrusion width W1A beyond the second inner spacer portion 150B1 in a direction away from the sub-gate portion 160S of the gate line 160 in the first lateral direction (X direction). The protrusion width W1A of the first inner spacer portion 150A1 may be selected from a range of about 0.5 nm to about 7 nm, for example, a range of about 1 nm to about 6 nm, without being limited thereto.

In embodiments of the present inventive concept, in a vertical direction (Z direction), a height A1H of the first inner spacer portion 150A1 of the interface insulating film 151 may be greater than or equal to a height B1H of the second inner spacer portion 150B1 of the interface insulating film 151. In the interface insulating film 151, the height A1H of the first inner spacer portion 150A1 may be less than the first thickness A1W of the first inner spacer portion 150A1.

In the IC device 100A shown in FIG. 4, the second inner spacer portion 150B1 of the interface insulating film 151 may fill a corner space defined by any one of the first to fourth nanosheets N1, N2, N3, and N4 and the source/drain region 130 by a relatively small thickness in a portion where the one nanosheet meets the source/drain region 130. Accordingly, problems, such as the formation of an undesired potential barrier near a portion of the source/drain region 130, which is adjacent to the first nanosheet N1, the second nanosheet N2, the third nanosheet N3, or the fourth nanosheet N4, or the formation of a depletion region through which carriers cannot pass at a channel entrance, may be prevented.

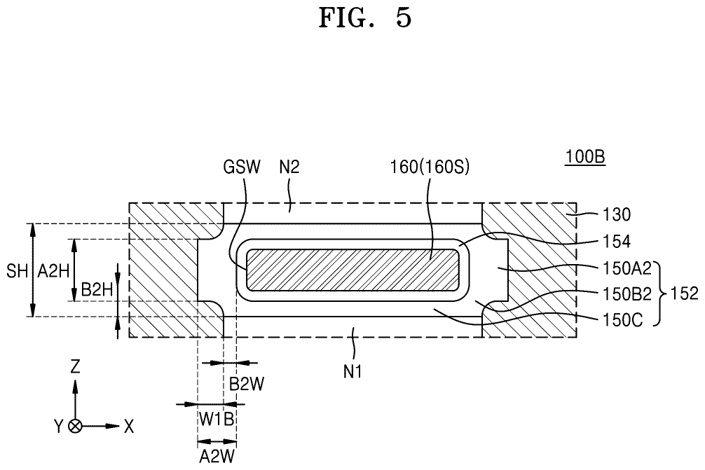

Referring to FIG. 5, the IC device 100B may include an interface insulating film 152 and a high-k dielectric film 154 between the nanosheet stack NSS and the gate line 160. The interface insulating film 152 may substantially have the same configuration as the interface insulating film 150, which has been described with reference to FIGS. 2A, 2B, 3A, and 3B. However, the interface insulating film 152 may include a first inner spacer portion 150A2 and a second inner spacer portion 150B2, which are between the sidewall GSW of the sub-gate portion 160S of the gate line 160 and the source/drain region 130 and integrally connected to each other. The first inner spacer portion 150A2 and the second inner spacer portion 150B2 may be referred to as an inner spacer.

In the interface insulating film 152, the first inner spacer portion 150A2 may be spaced apart from each of the first to fourth nanosheets N1, N2, N3, and N4 and protrude toward the source/drain region 130, while covering the sidewall GSW, which faces the source/drain region 130, of the sub-gate portion 160S of the gate line 160. In the interface insulating film 152, the second inner spacer portion 150B2 may extend from the first inner spacer portion 150A2 toward one nanosheet adjacent thereto, from among the first to fourth nanosheets N1, N2, N3, and N4, and contact the adjacent one nanosheet.

In the interface insulating film 152, the first inner spacer portion 150A2 may have a first thickness A2W in the first lateral direction (X direction), and the second inner spacer portion 150B2 may have a second thickness B2W, which is less than the first thickness A2W in the first lateral direction (X direction). In embodiments of the present inventive concept, the first thickness A2W may be selected from a range of about 1.5 nm to about 5 nm, without being limited thereto. The second thickness B2W may be less than the first thickness A2W and have a value selected from a range of about 1 nm to about 3 nm, without being limited thereto.

The first inner spacer portion 150A2 may protrude by a protrusion width W1B beyond than the second inner spacer portion 150B2 in a direction away from the sub-gate portion 160S of the gate line 160 in the first lateral direction (X direction). The protrusion width W1B of the first inner spacer portion 150A2 may be selected from a range of about 0.5 nm to about 4 nm, for example, a range of about 1 nm to about 3 nm, without being limited thereto.

In embodiments of the present inventive concept, in the vertical direction (Z direction), a height A2H of the first inner spacer portion 150A2 of the interface insulating film 152 may be greater than a height B2H of the second inner spacer portion 150B2 of the interface insulating film 152. In the interface insulating film 152, the height A2H of the first inner spacer portion 150A2 may be greater than the first thickness A2W of the first inner spacer portion 150A2.

In the IC device 100B shown in FIG. 5, the second inner spacer portion 150B2 of the interface insulating film 152 may fill a corner space that is defined by any one of the first to fourth nanosheets N1, N2, N3, and N4 and the source/drain region 130 by a relatively small thickness in a portion where the one nanosheet meets the source/drain region 130. Accordingly, problems, such as the formation of an undesired potential barrier near a portion of the source/drain region 130, which is adjacent to the first nanosheet N1, the second nanosheet N2, the third nanosheet N3, or the fourth nanosheet N4, or the formation of a depletion region through which carriers cannot pass at a channel entrance, may be prevented.

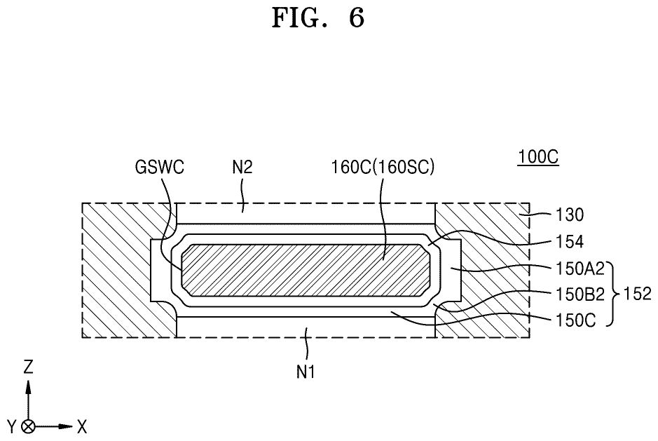

Referring to FIG. 6, the IC device 100C may have substantially the same configuration as the IC device 100B, which has been described with reference to FIG. 5. However, in the IC device 100C, a sub-gate portion 160SC of the gate line 160C may include a sidewall GSWC of the sub-gate portion 160SC facing the source/drain region 130. The sub-gate portion 160SC of the gate line 160C may have a shape with a length in the vertical direction (Z direction), which gradually reduces toward the sidewall GSWC in the first lateral direction (X direction).

A partial region of the sub-gate portion 160SC of the gate line 160C, which is adjacent to the sidewall GSWC, may overlap the second inner spacer portion 150B2 in the vertical direction (Z direction). Accordingly, in the IC device 100C, the second inner spacer portion 150B2 of the interface insulating film 152 may fill a corner space that is defined by any one of the first to fourth nanosheets N1, N2, N3, and N4 and the source/drain region 130 to a relatively small thickness in a portion where the one nanosheet meets the source/drain region 130. Therefore, problems, such as the formation of an undesired potential barrier near a portion of the source/drain region 130, which is adjacent to the first nanosheet N1, the second nanosheet N2, the third nanosheet N3, or the fourth nanosheet N4, or the formation of a depletion region through which carriers cannot pass at a channel entrance, may be effectively prevented.

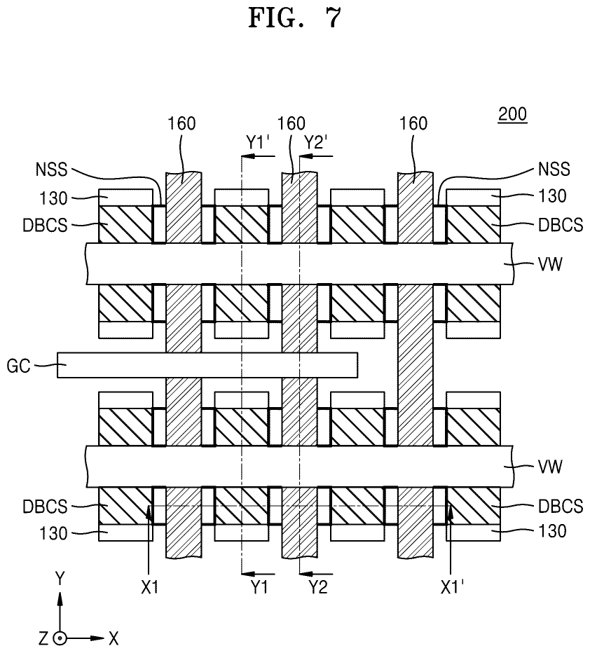

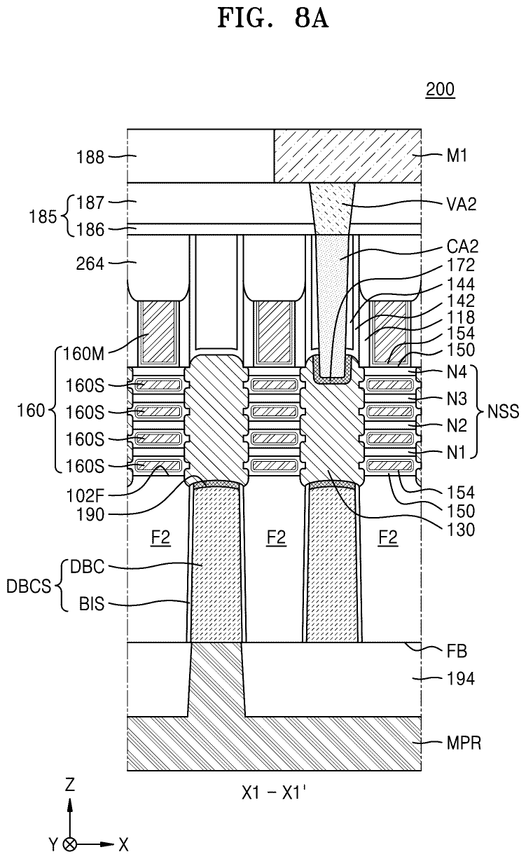

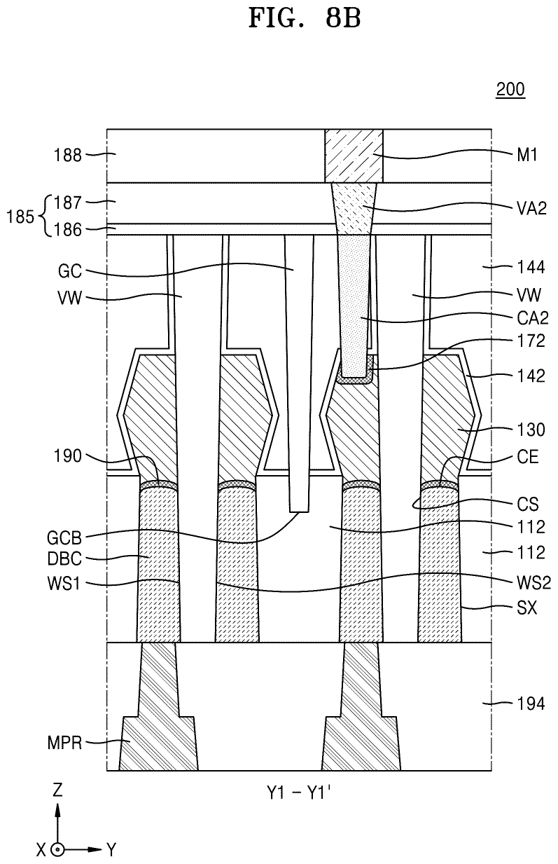

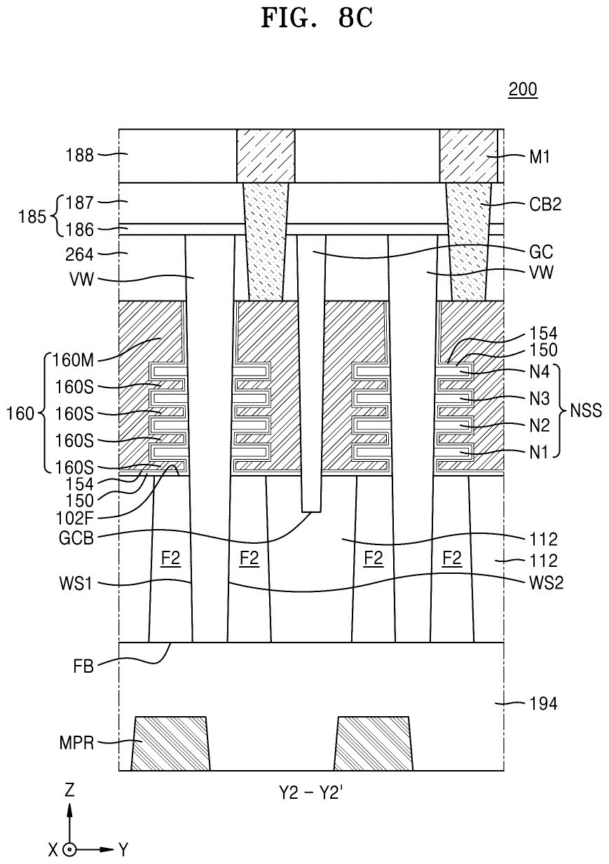

FIG. 7 is a plan layout diagram of an IC device 200 according to embodiments of the present inventive concept. FIG. 8A is a cross-sectional view taken along line X1-X1′ of FIG. 7. FIG. 8B is a cross-sectional view taken along line Y1-Y1′ of FIG. 7. FIG. 8C is a cross-sectional view taken along line Y2-Y2′ of FIG. 7. In FIGS. 7, 8A, 8B, and 8C, the same reference numerals are used to denote the same elements as in FIGS. 1 to 3B, and thus, detailed descriptions thereof are omitted.

Referring to FIGS. 7, 8A, 8B, and 8C, the IC device 200 may include a plurality of semiconductor regions F2, which are spaced apart from each other and arranged in a line in each of a first lateral direction (X direction) and a second lateral direction (Y direction), which are perpendicular to each other. In a view from above (on an X-Y plane), the plurality of semiconductor regions F2 may be arranged in a matrix form. Each of the plurality of semiconductor regions F2 may have a frontside surface 102F and a backside surface FB, which respectively face opposite directions to each other. In FIGS. 8A and 8C, the frontside surface 102F of each of the plurality of semiconductor regions F2 may be a surface facing a positive direction of a vertical direction (Z direction), and the backside surface FB of each of the plurality of semiconductor regions F2 may be a surface facing an opposite direction of the vertical direction (Z direction). Each of the plurality of semiconductor regions F2 may include silicon (Si).

A plurality of nanosheet stacks NSS may be on the plurality of semiconductor regions F2. The IC device 200 may include a plurality of source/drain regions 130. The plurality of source/drain regions 130 may be respectively adjacent to the plurality of nanosheet stacks NSS on both sides of the plurality of nanosheet stacks NSS in the first lateral direction (X direction). Each of the plurality of source/drain regions 130 may be between a pair of nanosheet stacks NSS, which are adjacent to each other in the first lateral direction (X direction), from among the plurality of nanosheet stacks NSS and be in contact with each of the first to fourth nanosheets N1, N2, N3, and N4 included in the nanosheet stack NSS adjacent thereto.

As shown in FIGS. 8B and 8C, the IC device 200 may include a plurality of insulating walls VW, which are adjacent to the plurality of semiconductor regions F2, the plurality of nanosheet stacks NSS, and the plurality of source/drain regions 130 and extend lengthwise in the first lateral direction (X direction). The plurality of insulating walls VW may be spaced apart from each other in a second lateral direction (Y direction) and extend parallel to each other in the first lateral direction (X direction). For example, the plurality of the insulating walls VW may contact the plurality of semiconductor regions F2, the plurality of nanosheet stacks NSS, and the plurality of source/drain regions 130. In embodiments of the present inventive concept, each of the plurality of insulating walls VW may include a silicon nitride film, a silicon carbonitride film (SiCN film), a silicon oxycarbonitride film (SiOCN film), a silicon oxide film, or a combination thereof, without being limited thereto.

Each of the plurality of insulating walls VW may pass in the vertical direction (Z direction) between a pair of semiconductor regions F2 that are adjacent to each other in the second lateral direction (Y direction), from among the plurality of semiconductor regions F2, between a pair of nanosheet stacks NSS that are adjacent to each other in the second lateral direction (Y direction), from among the plurality of nanosheet stacks NSS, and between a pair of source/drain regions 130 that are adjacent to each other in the second lateral direction (Y direction), from among the plurality of source/drain regions 130.

The pair of semiconductor regions F2, which are adjacent to each other in the second lateral direction (Y direction) with one insulation wall VW therebetween, may each contact the one insulation wall VW. The first to fourth nanosheets N1, N2, N3, and N4, which are in each of a pair of nanosheet stacks NSS that are adjacent to each other in the second lateral direction (Y direction) with one insulation wall VW therebetween, may contact the one insulation wall VW. Each of the first to fourth nanosheets N1, N2, N3, and N4 may contact the one insulation wall VW at one end in the second lateral direction (Y direction). A pair of source/drain regions 130, which are adjacent to each other in the second lateral direction (Y direction) with one insulation wall VW therebetween, may each contact the one insulation wall VW.

From among the both sidewalls of each of the plurality of semiconductor regions F2 in the second lateral direction (Y direction), a sidewall opposite to a sidewall facing the insulation wall VW may be covered by a field insulating film 112. Each of a plurality of field insulating films 112 may include, for example, a silicon oxide film, without being limited thereto.

On the semiconductor region F2, a plurality of gate lines 160 may be spaced apart from each other in the first lateral direction (X direction) and extend in the second lateral direction (Y direction). Each of the plurality of gate lines 160 may surround the first to fourth nanosheets N1, N2, N3, and N4, while covering a corresponding one of the plurality of nanosheet stacks NSS.

Each of the plurality of source/drain regions 130 may be adjacent to at least one gate line 160 selected from the plurality of gate lines 160. The plurality of source/drain regions 130, which are arranged in a line in the first lateral direction (X direction) may be respectively between the plurality of gate lines 160 one-by-one.

An interface insulating film 150 and a high-k dielectric film 154 may be between the nanosheet stack NSS and the gate line 160. Detailed configurations of the interface insulating film 150 and the high-k dielectric film 154 are substantially the same as those described with reference to FIGS. 2A, 2B, 3A, and 3B. However, in the IC device 200, the interface insulating film 150 and the high-k dielectric film 154 may surround the first to fourth nanosheets N1, N2, N3, and N4 while excluding surfaces of the first to fourth nanosheets N1, N2, N3, and N4 contacting the insulation wall VW, from among respective surfaces of the first to fourth nanosheets N1, N2, N3, and N4. In a cross-section taken in the second lateral direction (Y direction), the interface insulating film 150 may include a portion (referred to as a first interface insulating film portion) surrounding the first to fourth nanosheets N1, N2, N3, and N4 to surround surfaces excluding a surface contacting the insulation wall VW, from among respective surfaces of the first to fourth nanosheets N1, N2, N3, and N4, and the portion of the interface insulating film 150 may be disposed between the gate line 160 and each of the first to fourth nanosheets N1, N2, N3, and N4. The interface insulating film 150 may further include a portion (referred to as a second interface insulating film portion) contacting the insulation wall VW between the insulation wall VW and the gate line 160.

A plurality of gate lines 160, the plurality of nanosheet stacks NSS, and the plurality of source/drain regions 130 may constitute a plurality of nanosheet transistors. The plurality of nanosheets transistor may include an NMOS transistor, a PMOS transistor, or a combination thereof.

As shown in FIG. 8A, the both sidewalls of the gate line 160 may be covered by first insulating spacers 118. As shown in FIGS. 8A and 8C, the gate line 160, a top surface of each of the interface insulating film 150, the high-k dielectric film 154, and the first insulating spacer 118 may be covered by a capping insulating pattern 264. The capping insulating pattern 264 may include a silicon nitride film. The plurality of source/drain regions 130, the field insulating film 112, and the plurality of first insulating spacers 118 may be covered by an insulating liner 142. An inter-gate dielectric film 144 may be on the insulating liner 142.

As shown in FIGS. 8A and 8B, a plurality of frontside source/drain contacts CA2 may be on the plurality of source/drain regions 130 between a pair of adjacent ones of the plurality of gate lines 160. Each of the plurality of frontside source/drain contacts CA2 may be electrically connected to at least one source/drain region 130 selected from the plurality of source/drain regions 130. For example, one frontside source/drain contact CA2 may be connected to one source/drain region 130 or a plurality of source/drain regions 130 that are adjacent to each other. A detailed configuration of the frontside source/drain contact CA2 is substantially the same as that of the source/drain contact CA, which has been described with reference to FIGS. 2A and 2C.

A metal silicide film 172 may be between the source/drain region 130 and the frontside source/drain contact CA2. The metal silicide film 172 may constitute the source/drain region 130. The frontside source/drain contact CA2 may pass through the inter-gate dielectric film 144 and the insulating liner 142 in the vertical direction (Z direction) and contact the metal silicide film 172. The frontside source/drain contact CA2 may be connected to the source/drain region 130 through the metal silicide film 172.

As shown in FIGS. 8A and 8B, the IC device 200 may include a plurality of backside contact structures DBCS. Each of the plurality of backside contact structures DBCS may include a backside contact DBC and a backside insulating spacer BIS. The backside insulating spacer BIS may be between the backside contact DBC and the semiconductor region F2, which is most adjacent to the backside contact DBC. The backside contact DBC may be spaced apart from the semiconductor region F2 with the backside insulating spacer BIS therebetween in the first lateral direction (X direction).

The backside contact DBC of each of the plurality of backside contact structures DBCS may include a contact end CE that is connected to a selected one of the plurality of source/drain regions 130 and a contact sidewall CS that faces the insulation wall VW. Each of the plurality of backside contact structures DBCS may extend from the contact end CE toward the backside surface FB of the semiconductor region F2 in the vertical direction (Z direction). Of the backside contact DBC included in each of the plurality of backside contact structures DBCS, the contact sidewall CS facing the insulation wall VW that is adjacent thereto may contact the adjacent insulation wall VW.

The insulation wall VW may have a shape with a width in the second lateral direction (Y direction) that gradually reduces as the backside surface FB of the semiconductor region F2 is approached. Of the insulation wall VW, both sidewalls WS1 and WS2 contacting the backside contact DBC in the second lateral direction (Y direction) may include an inclined surface, which is inclined in the vertical direction (Z direction). The backside contact DBC may have a shape with a width in the second lateral direction (Y direction) gradually increasing as the backside surface FB of the semiconductor region F2 is approached. Of the backside contact DBC, the contact sidewall CS contacting the insulation wall VW may include an inclined surface corresponding to an inclined shape of the sidewalls WS1 and WS2 of the insulation wall VW.

A metal silicide film 190 may be between the source/drain region 130 and the backside contact structure DBCS. The metal silicide film 190 may contact the source/drain region 130 and the backside contact structure DBCS. As shown in FIG. 8A, the backside contact structure DBCS may pass between a pair of semiconductor regions F2, which are adjacent to each other in the first lateral direction (X direction), from among the plurality of semiconductor regions F2, in a vertical direction (Z direction) and contact the metal silicide film 190.

The backside contact DBC may be connected to the source/drain region 130 through the metal silicide film 190. A constituent material of the metal silicide film 190 is the same as that of the metal silicide film 172, which has been described above. In embodiments of the present inventive concept, the backside contact DBC may include only a metal plug, which includes a single metal. In embodiments of the present inventive concept, the backside contact DBC may include a metal plug and a conductive barrier film surrounding the metal plug. The metal plug may include, for example, molybdenum (Mo), tungsten (W), cobalt (Co), ruthenium (Ru), manganese (Mn), titanium (Ti), tantalum (Ta), aluminum (Al), copper (Cu), a combination thereof, or an ally thereof, without being limited thereto. The conductive barrier film may include a metal or a conductive metal nitride. For example, the conductive barrier film may include Ti, Ta, W, TiN, TaN, WN, WCN, TiSiN, TaSiN, WSiN, or a combination thereof, without being limited thereto.

Each of a plurality of backside contacts DBC may be connected to a surface opposite to a surface facing the inter-gate dielectric film 144, of a selected one of the plurality of source/drain regions 130.

As shown in FIG. 8B, the field insulating film 112 may cover an opposite sidewall SX that is opposite to the contact sidewall CS of the backside contact DBC, which is in contact with the insulation wall VW. The field insulating film 112 may contact the opposite sidewall SX of the backside contact DBC.

As shown in FIGS. 7, 8B, and 8C, the IC device 200 may include a gate cut insulating pattern GC, which defines lengths of the plurality of gate lines 160 in the second lateral direction (Y direction). The gate cut insulating pattern GC may face one end of each of the plurality of gate lines 160 corresponding thereto in the second lateral direction (Y direction) and have a shape extending lengthwise in the first lateral direction (X direction). The gate cut insulating pattern GC may pass through a portion of the field insulating film 112 in the vertical direction (Z direction). A lowermost surface GCB of the gate cut insulating pattern GC, which is closest to the backside surface FB of the semiconductor region F2, may be in contact with the field insulating film 112. The gate cut insulating pattern GC may include, for example, a silicon nitride film, silicon carbonitride film (SiCN film), a silicon oxycarbonitride film (SiOCN film), a silicon oxide film, or a combination thereof, without being limited thereto. As shown in FIGS. 8A to 8C, a top surface of each of the frontside source/drain contact CA2, a plurality of capping insulating patterns 264, and the inter-gate dielectric film 144 may be covered by an upper insulating structure 185. A source/drain via contact VA2 may be on the frontside source/drain contact CA2. The source/drain via contact VA2 may pass through the upper insulating structure 185 and contact the frontside source/drain contact CA2. From among the plurality of source/drain regions 130, the source/drain region 130 that is connected to the frontside source/drain contact CA2 may be electrically connected to the source/drain via contact VA2 through the metal silicide film 172 and the frontside source/drain contact CA2. Each of a plurality of source/drain via contacts VA2 may include, for example, molybdenum (Mo) or tungsten (W), without being limited thereto.

As shown in FIG. 8C, a gate contact CB2 may be on the gate line 160. The gate contact CB2 may pass through the upper insulating structure 185 and the capping insulating pattern 264 in the vertical direction (Z direction) and be connected to the gate line 160. A bottom surface of the gate contact CB2 may contact a top surface of the gate line 160. The gate contact CB2 may include a contact plug, which includes, for example, molybdenum (Mo), copper (Cu), tungsten (W), cobalt (Co), ruthenium (Ru), manganese (Mn), titanium (Ti), tantalum (Ta), aluminum (Al), a combination thereof, or an ally thereof, but a constituent material of the contact plug is not limited thereto. In embodiments of the present inventive concept, the gate contact CB2 may further include a conductive barrier pattern at least partially surrounding a portion of the contact plug. The conductive barrier pattern included in the gate contact CB2 may include a metal or a metal nitride. For example, the conductive barrier pattern may include, for example, Ti, Ta, W, TiN, TaN, WN, WCN, TiSiN, TaSiN, WSiN, or a combination thereof, without being limited thereto.

A top surface of the upper insulating structure 185 may be covered by a frontside interlayer insulating film 188. A constituent material of the frontside interlayer insulating film 188 may be substantially the same as that of the upper insulating film 187. A plurality of upper wiring layers M1 may be located to pass through the frontside interlayer insulating film 188. The plurality of upper wiring layers M1 may include an upper wiring layer M1, which is connected to the source/drain via contact VA2, and an upper wiring layer M1, which is connected to the gate contact CB2. The plurality of upper wiring layers M1 may include, for example, molybdenum (Mo), copper (Cu), tungsten (W), cobalt (Co), ruthenium (Ru), manganese (Mn), titanium (Ti), tantalum (Ta), aluminum (Al), a combination thereof, or an ally thereof, without being limited thereto.

As shown in FIGS. 8A to 8C, the IC device 200 may include a backside insulating film 194 covering the backside surface FB of each of the plurality of semiconductor regions F2 and a plurality of backside wiring structures MPR passing through the backside insulating film 194 in the vertical direction. The plurality of backside wiring structures MPR may include a backside wiring structure MPR that is connected to the backside contact DBC. In embodiments of the present inventive concept, a constituent material of the backside insulating film 194 is substantially the same as that of the upper insulating film 187. A constituent material of each of the plurality of backside wiring structures MPR is substantially the same as that of the plurality of upper wiring layers M1, which has been described above.

Similar to the IC device 100 described with reference to FIGS. 1, 2A to 2C, 3A, and 3B, the IC device 200 described with reference to FIGS. 7, 8A, 8B, and 8C may include the interface insulating film 150 surrounding the gate line 160, and the interface insulating film 150 may include a first inner spacer portion 150A, which is between a sidewall of a sub-gate portion 160S of the gate line 160 and the source/drain region 130, and a second inner spacer portion 150B, which extends from the first inner spacer portion 150A and contacts a nanosheet adjacent thereto. The second inner spacer portion 150B may have a smaller thickness than the first inner spacer portion 150A. Accordingly, a sufficient insulation distance may be ensured between the sidewall of the sub-gate portion 160S and the source/drain region 130 by the first inner spacer portion 150A having a relatively large thickness, and the second inner spacer portion 150B may cover a corner space defined by any one of the first to fourth nanosheets N1, N2, N3, and N4 and the source/drain region 130 by a relatively small thickness in a portion where the one nanosheet meets the source/drain region 130. Therefore, problems, such as the formation of an undesired potential barrier near a portion of the source/drain region 130, which is adjacent to the first nanosheet N1, the second nanosheet N2, the third nanosheet N3, or the fourth nanosheet N4, or the formation of a depletion region through which carriers cannot pass at a channel entrance, may be prevented. Accordingly, in the present inventive concept, even when the IC device 200 has a device region with a reduced area with the downscaling trend, undesired parasitic capacitance and leakage current, which may occur between the source/drain region 130 and the sub-gate portion 160S of the gate line 160 surrounding the first to fourth nanosheets N1, N2, N3, and N4 that provide a channel region, may be minimized, and gate controllability and current drivability may increase. Therefore, in the IC device 200 according to embodiments of the present inventive concept, the performance and reliability of an FET including a plurality of nanosheets (e.g., the first to fourth nanosheets N1, N2, N3, and N4) may increase.

Next, a method of manufacturing an IC device, according to embodiments of the present inventive concept, is described with reference to specific examples.

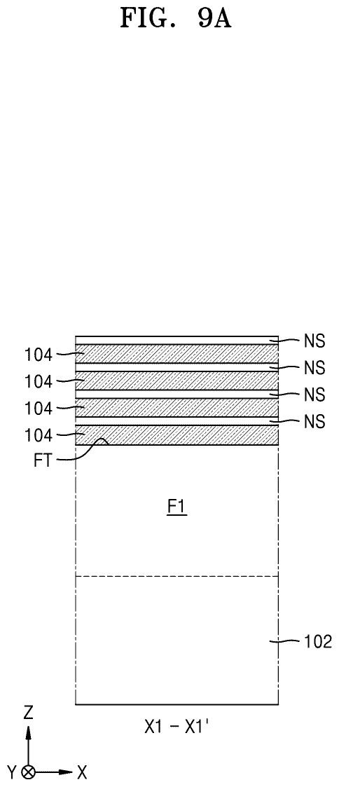

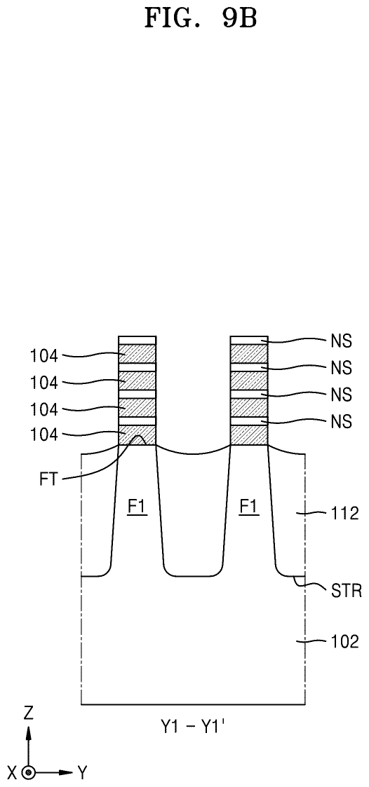

FIGS. 9A to 18B are cross-sectional views of a process sequence of a method of manufacturing an IC device, according to embodiments of the present inventive concept. More specifically, FIGS. 9A, 10A, 11, 12, 13, 14, 15A, 16, 17A, and 18A are cross-sectional views of some components of in a portion corresponding to a cross-section taken along line X1-X1′ of FIG. 1, according to a process sequence. FIGS. 9B, 10B, 15B, 17B, and 18B are cross-sectional views of some components of in a portion corresponding to a cross-section taken along line Y1-Y1′ of FIG. 1, according to a process sequence. An example of a method of manufacturing the IC device 100, which was described with reference to FIGS. 1, 2A to 2C, 3A, and 3B, is described with reference to FIGS. 9A to 18B. In FIGS. 9A to 18B. The same reference numerals are used to denote the same elements as in FIGS. 1, 2A to 2C, 3A, and 3B, and thus, detailed descriptions thereof are omitted.

Referring to FIGS. 9A and 9B, a multiple layer in which a plurality of sacrificial semiconductor layers 104 and a plurality of nanosheet semiconductor layers NS are alternately stacked one-by-one on a substrate 102, and a portion of each of the multiple layer and the substrate 102 may be etched, and thus, a device isolation trench STR may be formed in the substrate 102. As a result, a plurality of fin-type active regions F1 may be formed to protrude upward from the substrate 102 in a vertical direction (Z direction), and the plurality of sacrificial semiconductor layers 104 and the plurality of nanosheet semiconductor layers NS may remain elongated in a first lateral direction (X direction) on a fin top surface FT of each of the plurality of fin-type active regions F1.

The plurality of sacrificial semiconductor layers 104 and the plurality of nanosheet semiconductor layers NS may include materials having different etch selectivities from each other. In embodiments of the present inventive concept, the plurality of nanosheet semiconductor layers NS may each include a Si layer, and the plurality of sacrificial semiconductor layers 104 may each include a SiGe layer. In embodiments of the present inventive concept, A Ge content ratio may be constant in the plurality of sacrificial semiconductor layers 104. The SiGe layer included in the plurality of sacrificial semiconductor layers 104 may have a Ge content ratio selected from a range of about 5 atomic percent (at %) to about 60 at % (e.g., about 20 at % to about 40 at %). A Ge content ratio may be variously selected as needed in the SiGe layer included in the plurality of sacrificial semiconductor layers 104.

Thereafter, a field insulating film 112 filling the device isolation trench STR may be formed on the substrate 102. After the field insulating film 112 is formed, a level of a top surface of the field insulating film 112 may become lower than a level of the fin top surface FT of each of the plurality of fin-type active regions F1. In embodiments of the present inventive concept, the field insulating film 112 may be formed by using a CVD process. The field insulating film 112 may include a silicon oxide film.

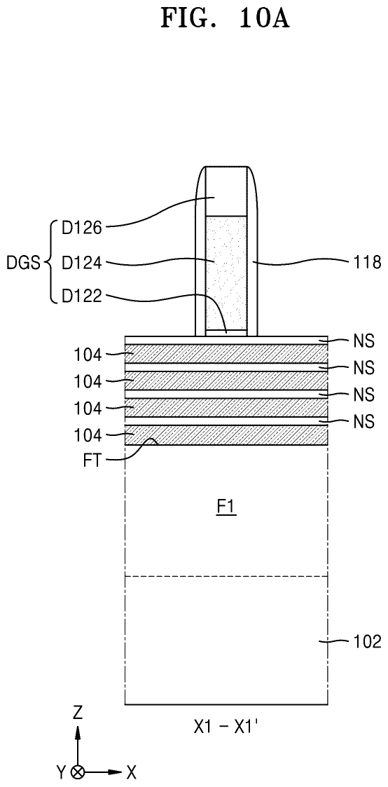

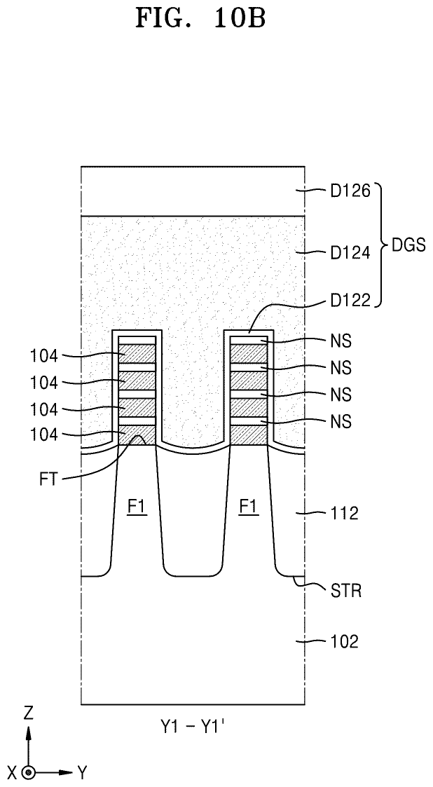

Referring to FIGS. 10A and 10B, a dummy gate structure DGS may be formed on the resultant structure of FIGS. 9A and 9B, and a plurality of first insulating spacers 118 may be formed to cover both sidewalls of the dummy gate structure DGS. During the formation of the plurality of first insulating spacers 118, the plurality of second insulating spacers 119 shown in FIG. 2C may also be formed.

The dummy gate structure DGS may be formed on the substrate 102 to extend lengthwise in a second lateral direction (Y direction) that intersects the fin-type active region F1. The dummy gate structure DGS may have a structure in which an oxide film D122, a dummy gate layer D124, and a capping layer D126 are sequentially stacked on the substrate 102. In embodiments of the present inventive concept, the dummy gate layer D124 may include polysilicon, and the capping layer D126 may include a silicon nitride film.

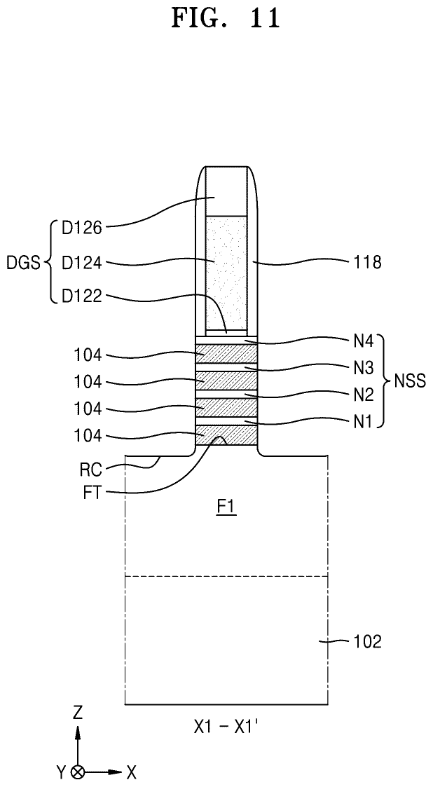

Referring to FIG. 11, respective portions of the plurality of sacrificial semiconductor layers 104 and the plurality of nanosheet semiconductor layers NS and portions of the fin-type active region F1 may be etched by using the dummy gate structure DGS and the plurality of first insulating spacers 118 as etch masks. The plurality of nanosheet semiconductor layers NS may be divided into a plurality of nanosheet stacks NSS, and a plurality of recesses RC may be formed in an upper portion of the fin-type active region F1. Each of the plurality of nanosheet stacks NSS may include first to fourth nanosheets N1, N2, N3, and N4. The plurality of recesses RC may be formed by using a dry etching process, a wet etching process, or a combination thereof. After the plurality of recesses RC are formed, a resultant structure in which the plurality of second insulating spacers 119 protrude upward from a bottom surface of the recess RC may be obtained as shown in FIG. 2C.

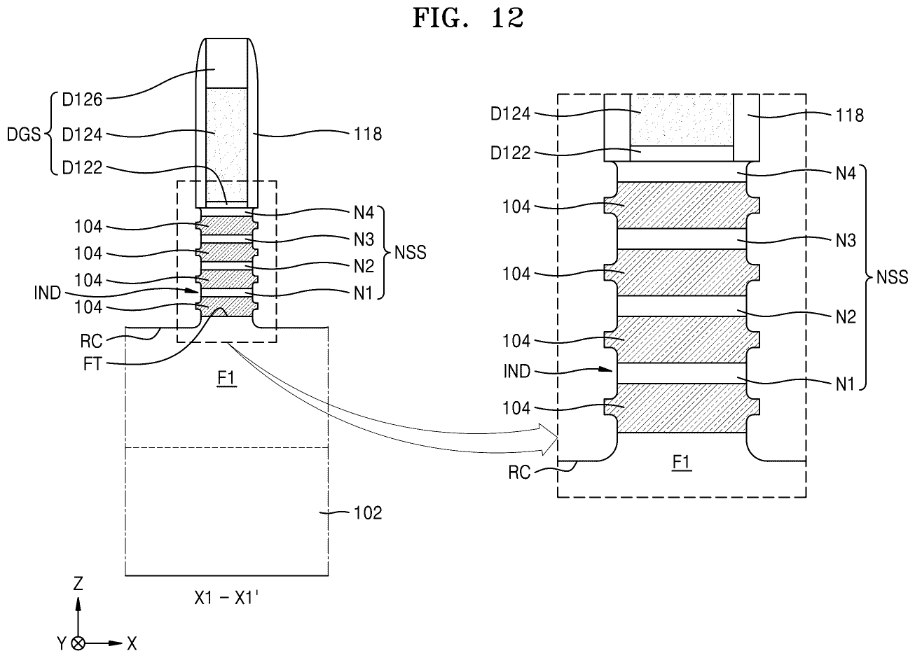

Referring to FIG. 12, in the resultant structure of FIG. 11, portions of respective sidewalls of the first to fourth nanosheets N1, N2, N3, and N4 exposed through the recess RC may be removed to form a plurality of indent spaces IND, which are indented more inward than respective sidewalls of the plurality of sacrificial semiconductor layers 104 in the first lateral direction (X direction). To form the plurality of indent spaces IND, by controlling a difference between an etch rate of the first to fourth nanosheets N1, N2, N3, and N4 and an etch rate of the plurality of sacrificial semiconductor layers 104 during the etching of the portions of the first to fourth nanosheets N1, N2, N3, and N4, portions of the plurality of sacrificial semiconductor layers 104 exposed at the plurality of indent spaces may be etched together. As a result, a length of each of the plurality of indent spaces IND in the vertical direction (Z direction) may become greater than a length of each of the first to fourth nanosheets N1, N2, N3, and N4 in the vertical direction (Z direction).

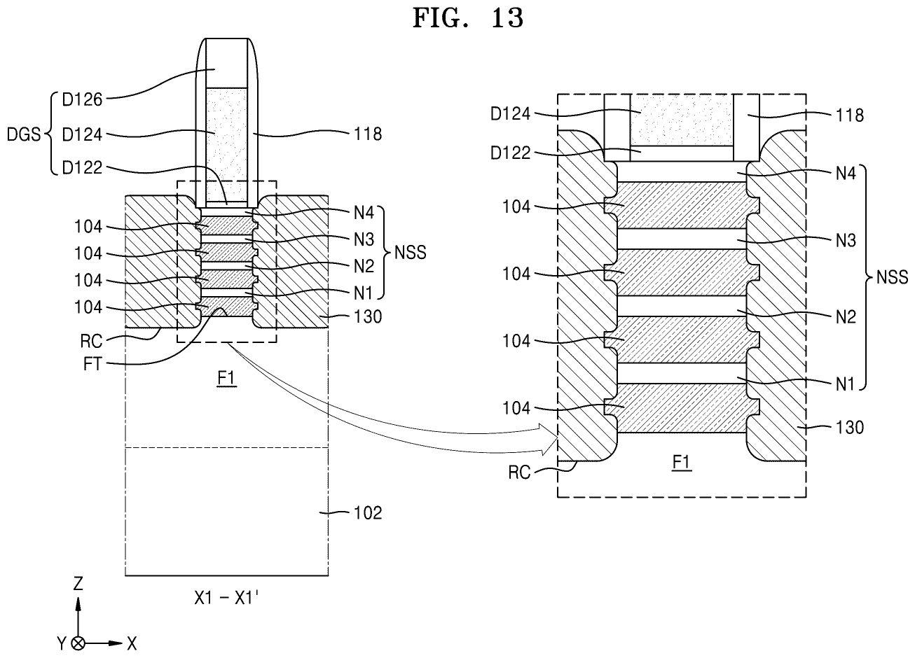

Referring to FIG. 13, in the resultant structure of FIG. 12, a plurality of source/drain regions 130 may be formed to at least partially fill the plurality of recesses RC. To form the plurality of source/drain regions 130, a semiconductor material may be epitaxially grown from a surface of the fin-type active region F1, which is exposed at a bottom surface of each of the plurality of recesses RC, an exposed surface of each of the first to third nanosheets N1, N2, and N3 exposed through the plurality of indent spaces IND, and an exposed surface of each of the plurality of sacrificial semiconductor layers 104.

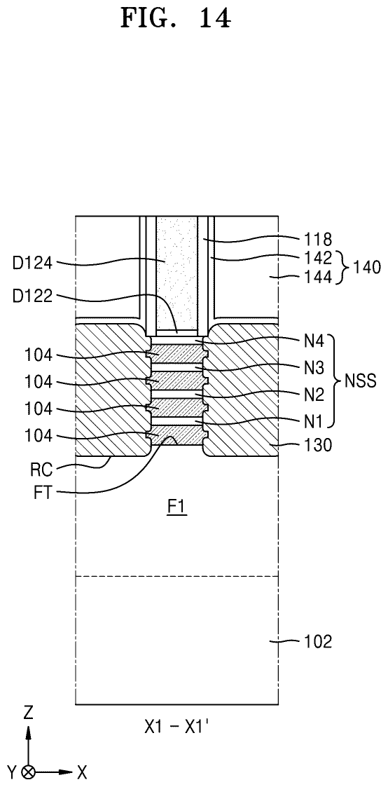

Referring to FIG. 14, an insulating liner 142 may be formed to cover the resultant structure of FIG. 13, and an inter-gate dielectric film 144 may be formed on the insulating liner 142 to form an inter-gate dielectric structure 140. Next, a portion of the inter-gate dielectric structure 140 may be etched to expose top surfaces of a plurality of capping layers D126. Thereafter, the dummy gate layer D124 may be exposed by removing the plurality of capping layers D126, and the inter-gate dielectric structure 140 may be partially removed such that a top surface of the inter-gate dielectric structure 140 and a top surface of the dummy gate layer D124 become substantially coplanar with each other.

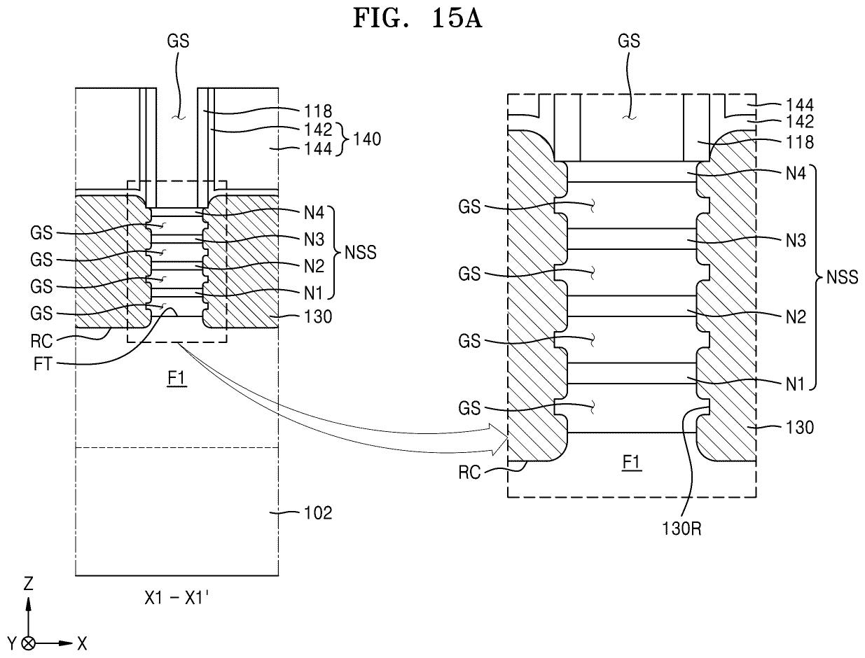

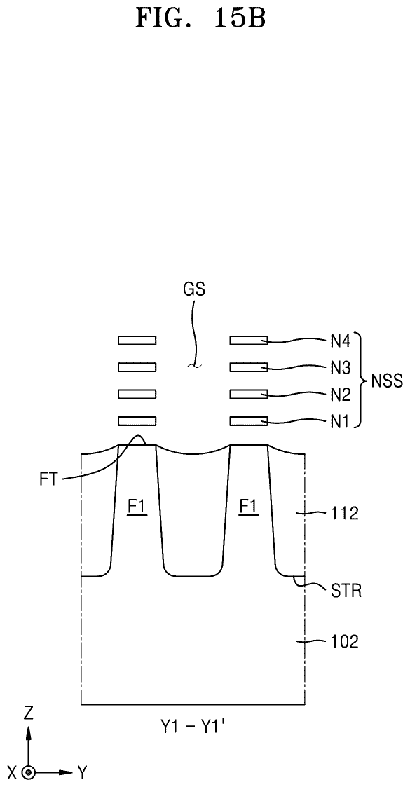

Referring to FIGS. 15A and 15B, a gate space GS may be prepared by removing the dummy gate layer D124 and the oxide film D122 located thereunder from the resultant structure of FIG. 14, and the plurality of nanosheet stacks NSS may be exposed through the gate space GS. Afterwards, the plurality of sacrificial semiconductor layers 104 remaining on the fin-type active region F1 may be removed through the gate space GS, and thus, the gate space GS may extend to respective spaces between the first to fourth nanosheets N1, N2, N3, and N4 and a space between the first nanosheet N1 and the fin top surface FT of the fin-type active region F1.

To selectively remove the plurality of sacrificial semiconductor layers 104, etch selectivities of the first to fourth nanosheets N1, N2, N3, and N4 with respect to the plurality of sacrificial semiconductor layers 104 may be used. A liquid or gaseous etchant may be used to selectively remove the plurality of sacrificial semiconductor layers 104. In embodiments of the present inventive concept, to selectively remove the plurality of sacrificial semiconductor layers 104, a CH₃COOH-based etchant, for example, an etchant including a mixture of CH₃COOH, HNO₃, and HF or an etchant including a mixture of CH₃COOH, H₂O₂, and HF may be used, without being limited thereto.

After the plurality of sacrificial semiconductor layers 104 are removed, the side recess portion 130R may be exposed in each of the plurality of source/drain regions 130. A length of the side recess portion 130R in the vertical direction (Z direction) may be less than a length of a space between two adjacent ones of the first to fourth nanosheets N1, N2, N3, and N4 in the vertical direction (Z direction).

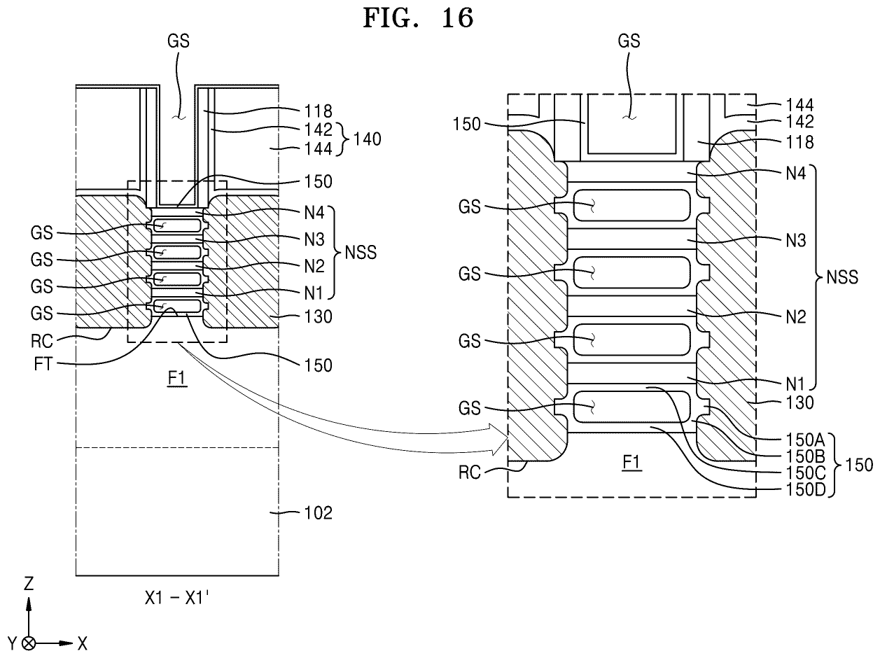

Referring to FIG. 16, in the resultant structure of FIGS. 15A and 15B, an interface insulating film 150 may be formed to cover respective exposed surfaces of the first to fourth nanosheets N1, N2, N3, and N4 and the fin-type active region FA.

During the formation of the interface insulating film 150, a relatively small space that is defined by the side recess portion 130R of each of the plurality of source/drain regions 130 may be filled by the interface insulating film 150. Thus, of the interface insulating film 150, a thickness of the first inner spacer portion 150A filling the space that is defined by the side recess portion 130R in the first lateral direction (X direction) may become greater than a thickness in the first lateral direction (X direction) of the second inner spacer portion 150B, which extends from the first inner spacer portion 150A toward one nanosheet adjacent thereto, from among the first to fourth nanosheets N1, N2, N3, and N4.

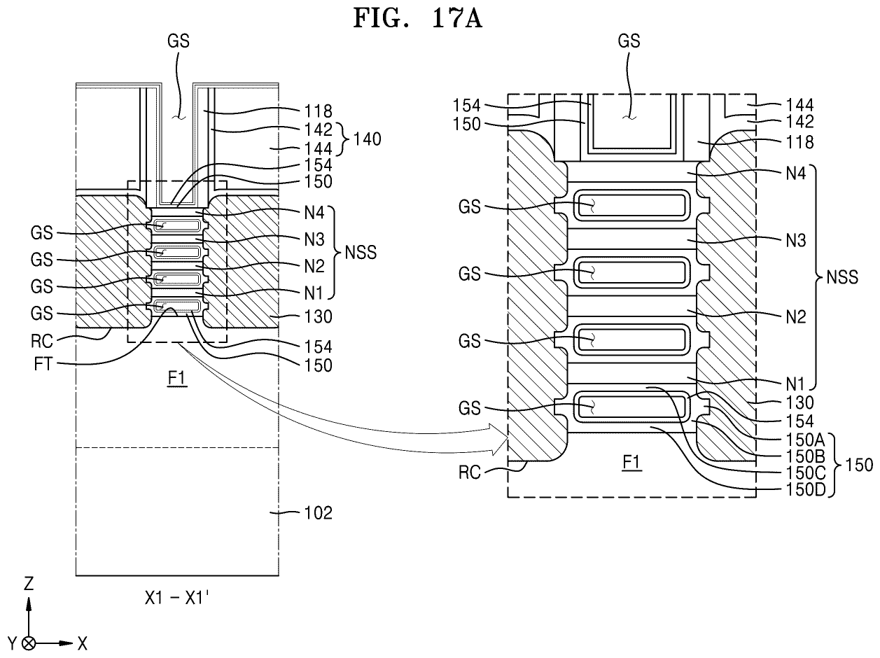

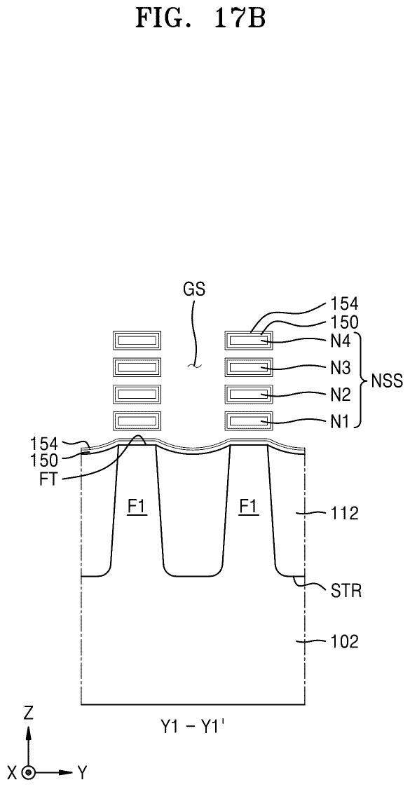

Referring to FIGS. 17A and 17B, in the resultant structure of FIG. 16, a high-k dielectric film 154 may be formed to conformally cover a surface of the interface insulating film 150. For example, the high-k dielectric film 154 may be formed by using an atomic layer deposition (ALD) process.

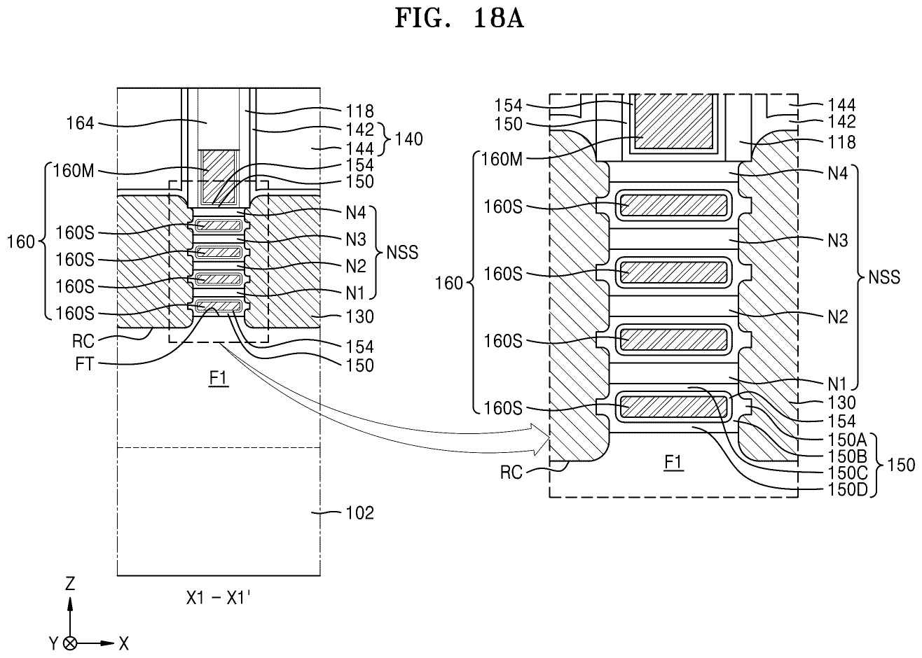

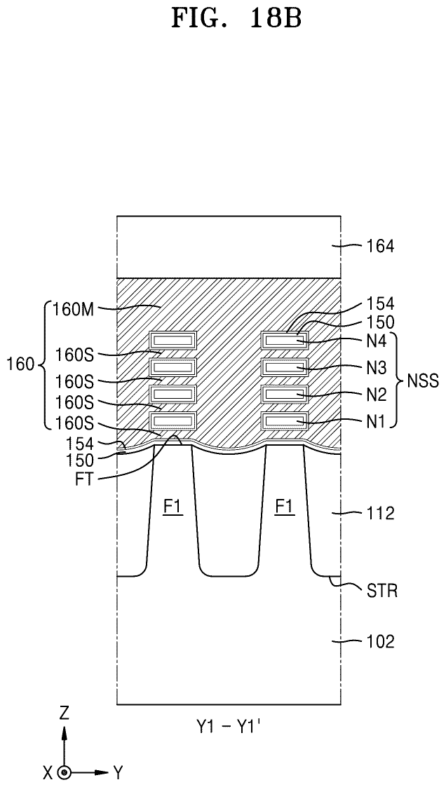

Referring to FIGS. 18A and 18B, a gate line 160 filling the gate space (refer to GS in FIGS. 17A and 17B) may be formed on the high-k dielectric film 154. Next, portions of the gate line 160, the interface insulating film 150, and the high-k dielectric film 154 may be removed from top surfaces thereof to reduce respective heights of the gate line 160, the interface insulating film 150, and the high-k dielectric film 154, and a plurality of capping insulating patterns 164 may be formed to cover the top surface of each of the gate line 160, the interface insulating film 150, and the high-k dielectric film 154.

Subsequently, as shown in FIGS. 2A to 2C, partial regions of the inter-gate dielectric structure 140 may be etched to form a plurality of source/drain contact holes exposing the plurality of source/drain regions 130, and a metal silicide film 172 may be formed on a surface of the source/drain region 130, which is exposed through each of the plurality of source/drain contact holes. A conductive barrier film 174 and a metal plug 176 may be sequentially formed on the metal silicide film 172, and thus, a plurality of source/drain contacts CA may be formed to fill the plurality of source/drain contact holes.

Thereafter, an etch stop film 186 and an upper insulating film 187 may be sequentially formed to cover a top surface of each of the plurality of source/drain contacts CA, the capping insulating pattern 164, and the inter-gate dielectric structure 140 to form an upper insulating structure 185. Afterwards, a source/drain via contact VA may be formed to pass through the upper insulating structure 185 in the vertical direction (Z direction) and be connected to the source/drain contact CA. A gate contact CB may be formed to pass through the upper insulating structure 185 and the capping insulating pattern 164 in the vertical direction (Z direction) and be connected to the gate line 160. The source/drain via contact VA and the gate contact CB may be formed simultaneously or by using separate processes.

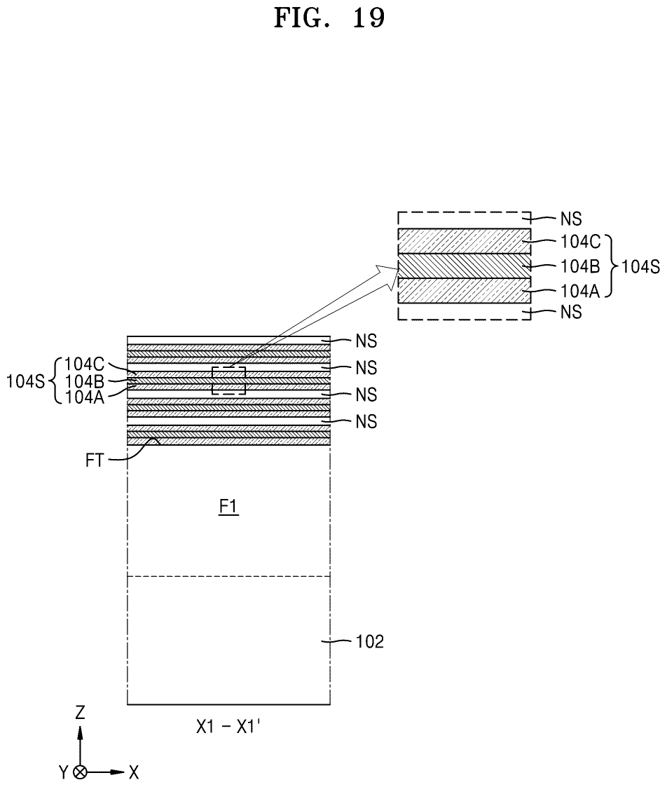

FIGS. 19 to 21 are cross-sectional views of some components in a portion corresponding to a cross-section taken along line X1-X1′ of FIG. 1, illustrating a process sequence of a method of manufacturing an IC device, according to embodiments of the present inventive concept. Another example of a method of manufacturing the IC device 100, which is described with reference to FIGS. 1, 2A to 2C, 3A, and 3B, is described with reference to FIGS. 19 to 21. In FIGS. 19 to 21, the same reference numerals are used to denote the same elements as in FIGS. 1, 2A to 2C, 3A, and 3B, and thus, detailed descriptions thereof are omitted.

Referring to FIG. 19, the processes described with reference to FIGS. 9A and 9B may be performed. However, in the present embodiment, a plurality of sacrificial semiconductor layers 104S may be formed instead of the plurality of sacrificial semiconductor layers 104. Each of the plurality of sacrificial semiconductor layers 104S may have a multilayered structure including a first sacrificial semiconductor sub-layer 104A, a second sacrificial semiconductor sub-layer 104B, and a third sacrificial semiconductor sub-layer 104C, which are sequentially stacked in a vertical direction (Z direction).

Each of the first sacrificial semiconductor sub-layer 104A, the second sacrificial semiconductor sub-layer 104B, and the third sacrificial semiconductor sub-layer 104C may include, for example, a silicon germanium (SiGe) layer. However, a Ge content ratio of the second sacrificial semiconductor sub-layer 104B interposed between the first sacrificial semiconductor sub-layer 104AA and the third sacrificial semiconductor sub-layer 104C may be lower than a Ge content ratio of each of the first sacrificial semiconductor sub-layer 104A and the third sacrificial semiconductor sub-layer 104C. In embodiments of the present inventive concept, the second sacrificial semiconductor sub-layer 104B may have a Ge content ratio selected from a range of about 20 at % or more and less than about 30 at %, and the first sacrificial semiconductor sub-layer 104A and the third sacrificial semiconductor sub-layer 104C may have a Ge content ratio selected from a range of about 30 at % to about 40 at %. For example, the second sacrificial semiconductor sub-layer 104B may have a Ge content ratio of about 25 at %, and each of the first sacrificial semiconductor sub-layer 104A and the third sacrificial semiconductor sub-layer 104C may have a Ge content ratio of about 35 at %, without being limited thereto.

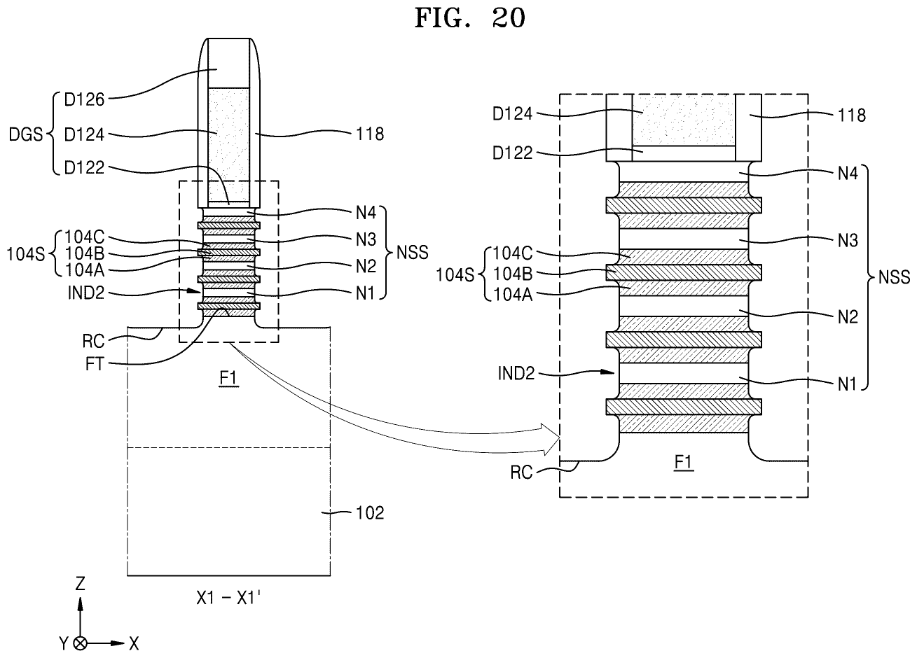

Referring to FIG. 20, the processes described with reference to FIGS. 10A and 10B and the processes described with reference to FIG. 11 may be sequentially performed on the resultant structure of FIG. 19.

Thereafter, similar to that described with reference to FIG. 12, portions of respective sidewalls of the first to fourth nanosheets N1, N2, N3, and N4 exposed through the recess RC may be removed to form a plurality of indent spaces IND2, which are indented more inward than respective sidewalls of portions of the plurality of sacrificial semiconductor layers 104S in the first lateral direction (X direction). To form the plurality of indent spaces IND2, by controlling a difference between an etch rate of the first to fourth nanosheets N1, N2, N3, and N4 and an etch rate of each of the first sacrificial semiconductor sub-layer 104A and the third sacrificial semiconductor sub-layer 104C included in the plurality of sacrificial semiconductor layers 104S during the etching of a portion of each of the first to fourth nanosheets N1, N2, N3, and N4, a portion of each of the first sacrificial semiconductor sub-layer 104A and the third sacrificial semiconductor sub-layer 104C exposed at the plurality of indent spaces IND2 may be etched together. As a result, a length of each of the plurality of indent spaces IND2 in the vertical direction (Z direction) may become greater than a length of each of the first to fourth nanosheets N1, N2, N3, and N4 in the vertical direction (Z direction).

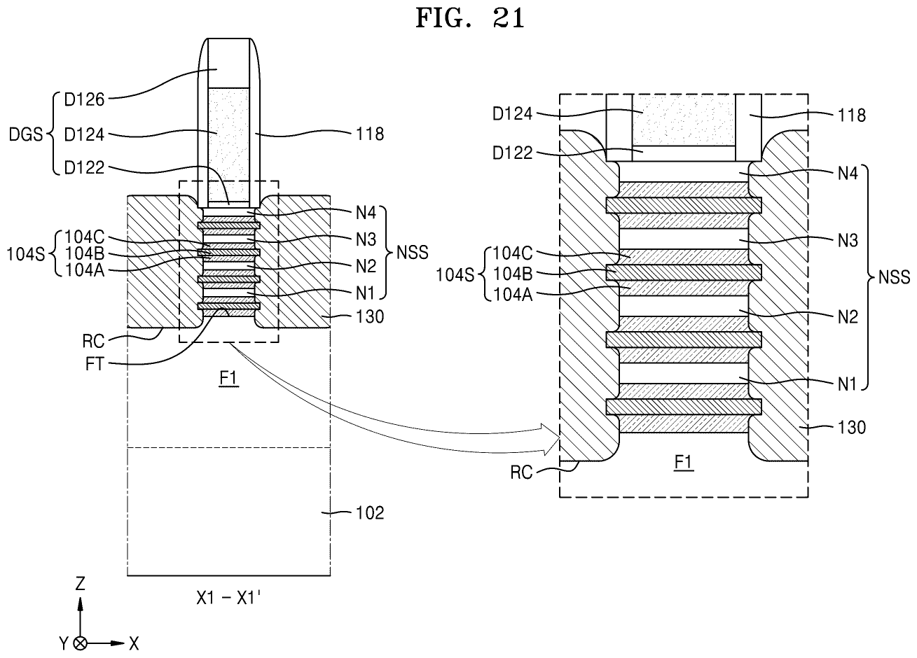

Referring to FIG. 21, in the resultant structure of FIG. 20, a plurality of source/drain regions 130 may be formed to fill the plurality of recesses RC. To form the plurality of source/drain regions 130, a semiconductor material may be epitaxially grown from a surface of the fin-type active region F1, which is exposed at bottom surfaces of the plurality of recesses RC, an exposed surface of each of the first to fourth nanosheets N1, N2, N3, and N4 that are included in the nanosheet stack NSS, and an exposed surface of each of the plurality of sacrificial semiconductor layers 104S.

Subsequently, the processes described with reference to FIGS. 14 to 18B may be performed on the resultant structure of FIG. 21, and thus, the IC device 100 shown in FIGS. 1, 2A to 2C, 3A, and 3B may be manufactured.

Although the methods of manufacturing the IC device 100 shown in FIGS. 1, 2A to 2C, 3A, and 3B have been described with reference to FIGS. 9A to 21, it will be understood that the IC devices 100A, 100B, and 100C shown in FIGS. 4, 5, and 6 may be manufactured by applying various modifications and changes to the processes described with reference to FIGS. 9A to 21 within the scope of the present inventive concept.

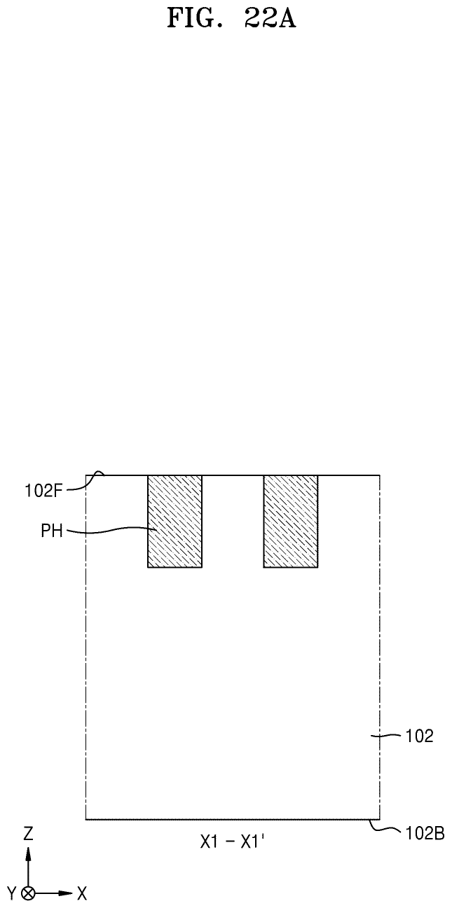

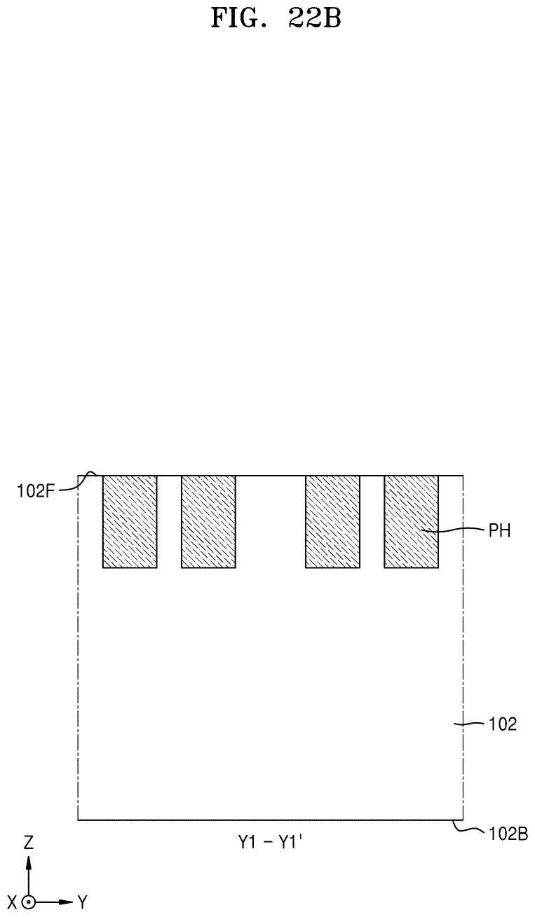

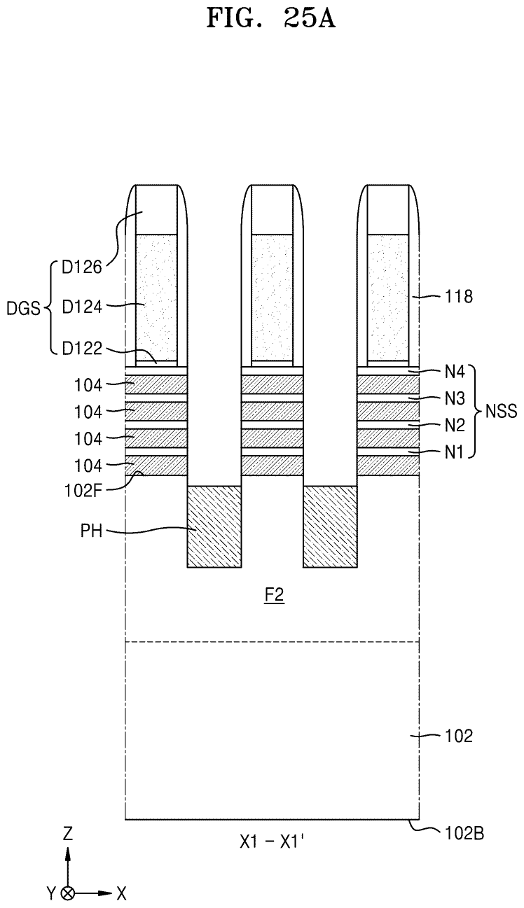

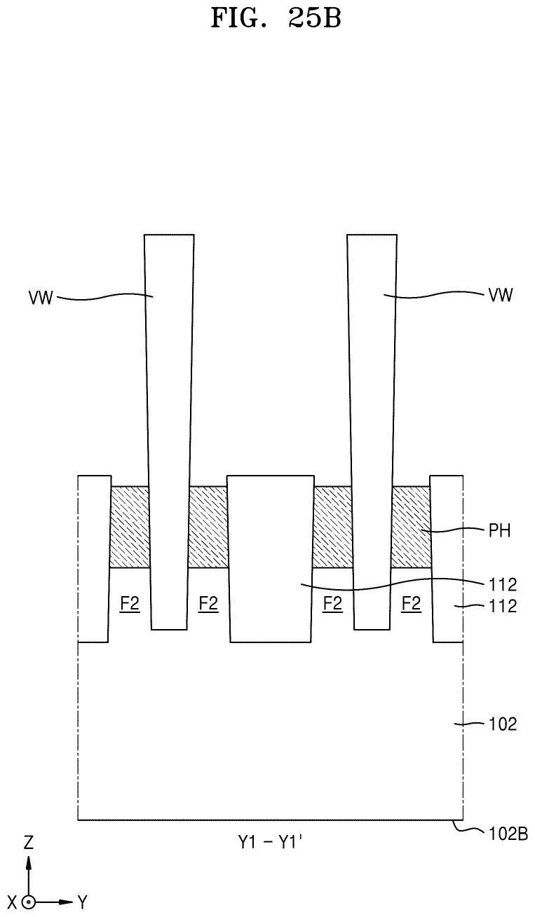

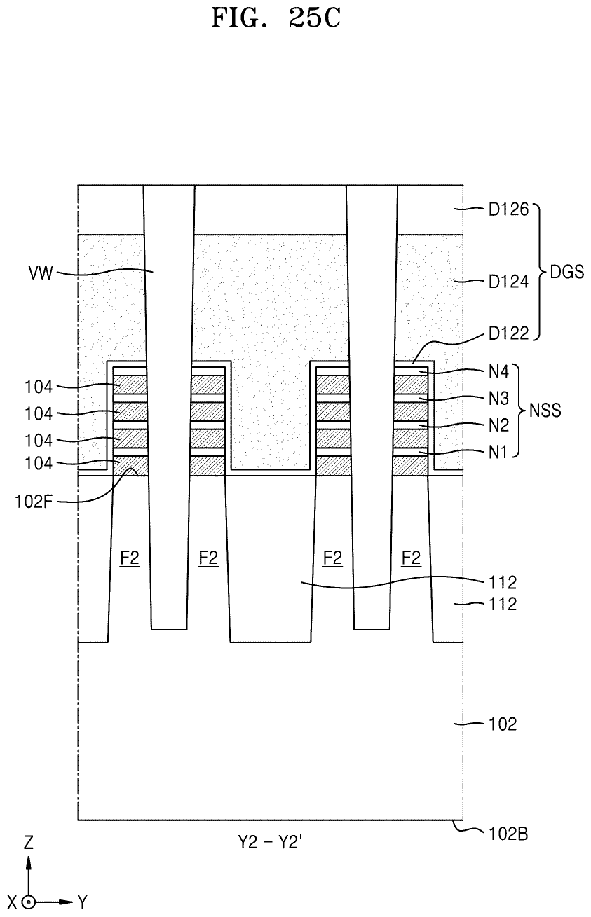

FIGS. 22A to 33B are cross-sectional views of a process sequence of a method of manufacturing an IC device, according to embodiments of the present inventive concept. More specifically, FIGS. 22A, 23A, 24A, 25A, 26A, 27A, 28A, 29A, 30A, 31A, 32A, and 33A are cross-sectional views of example structures of a portion corresponding to a cross-section taken along line X1-X1′ of FIG. 7, according to a process sequence. FIGS. 22B, 23B, 24B, 25B, 26B, 29B, 30B, 31B, 32B, and 33B are cross-sectional views of example structures of a portion corresponding to a cross-section taken along line Y1-Y1′ of FIG. 7, according to a process sequence. FIGS. 25C, 27B, 28B, 29C, 30C, and 31C are cross-sectional views of example structures of a portion corresponding to a cross-section taken along line Y2-Y2′ of FIG. 7, according to a process sequence. An example of a method of manufacturing the IC device 200, which is described with reference to FIGS. 7, 8A, 8B, and 8C, is described with reference to FIGS. 22A to 33B. In FIGS. 22A to 33B, the same reference numerals are used to denote the same elements as in FIGS. 1 to 8C, and thus, detailed descriptions thereof are omitted.

Referring to FIGS. 22A and 22B, a substrate 102 having a frontside surface 102F and a backside surface 102B that are opposite to each other may be provided, and a partial region of the substrate 102 may be etched from the frontside surface 102F of the substrate 102 by using a photolithography process, and thus, a plurality of place holder spaces may be formed in the substrate 102. Thereafter, a plurality of place holders PH may be formed to fill the plurality of place holder spaces.

In embodiments of the present inventive concept, each of the plurality of place holders PH may include a doped SiGe film, an undoped SiGe film, a polysilicon film, a silicon nitride film, a silicon carbonitride film (or a SiCN film), a silicon oxycarbonitride film (or a SiOCN film), a silicon oxide film, or a combination thereof, without being limited thereto.

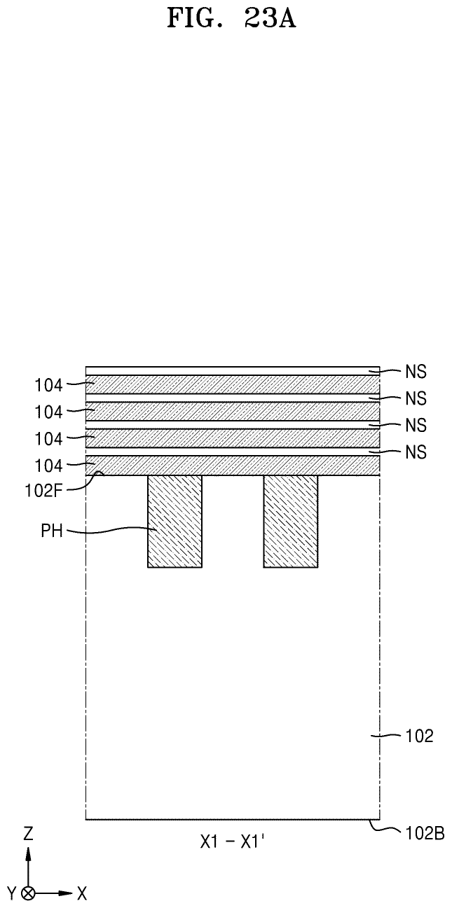

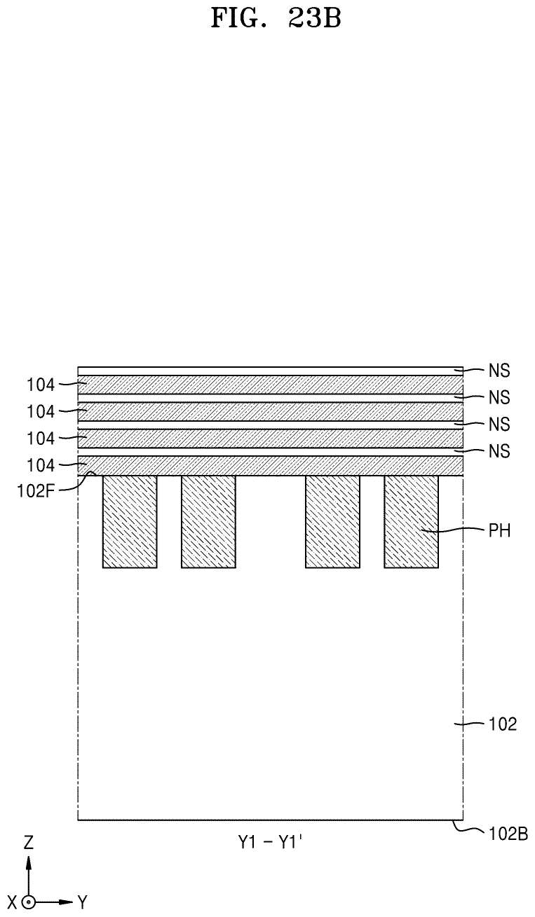

Referring to FIGS. 23A and 23B, in the resultant structure of FIGS. 22A and 22B, a stack structure, in which a plurality of sacrificial semiconductor layers 104 and a plurality of nanosheet semiconductor layers NS may be alternately stacked one-by-one, may be formed on the plurality of place holders PH and the frontside surface 102F of the substrate 102. Detailed configurations of the plurality of sacrificial semiconductor layers 104 and the plurality of nanosheet semiconductor layers NS are the same as those described with reference to FIGS. 9A and 9B.

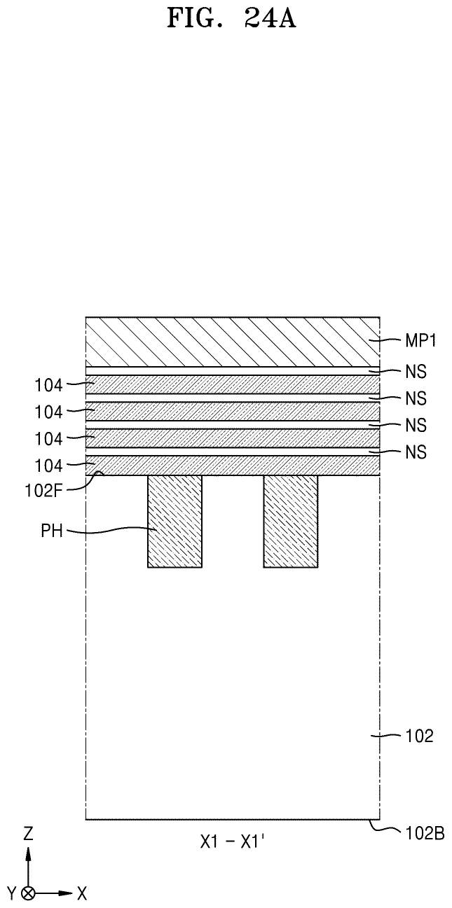

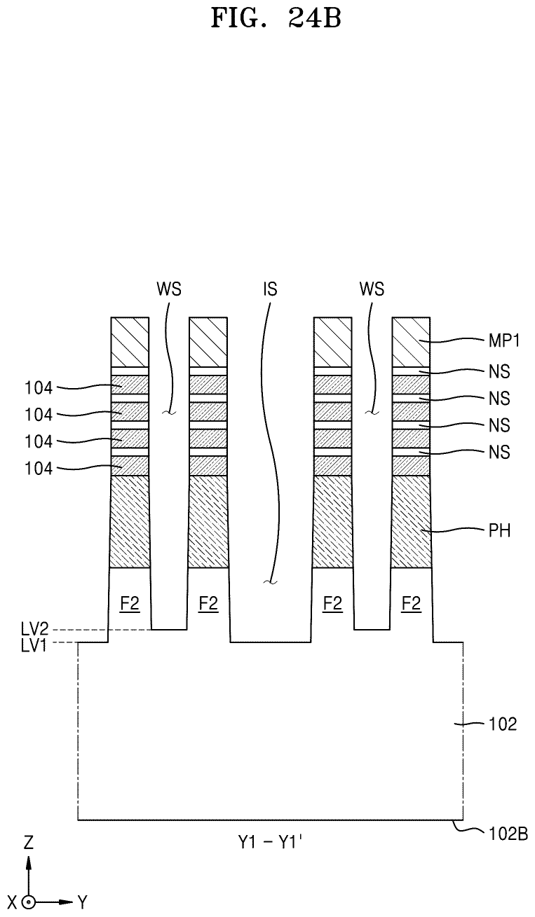

Referring to FIGS. 24A and 24B, a mask pattern MP1 having openings exposing a top surface of the stack structure including the plurality of sacrificial semiconductor layers 104 and the plurality of nanosheet semiconductor layers NS may be formed on the resultant structure of FIGS. 23A and 23B. The mask pattern MP1 may have a stack structure of a silicon oxide film pattern and a silicon nitride film pattern. The mask pattern MP1 may include portions extending parallel to each other in a first lateral direction (X direction) on the substrate 102.

Respective portions of the plurality of sacrificial semiconductor layers 104, the plurality of nanosheet semiconductor layers NS, the plurality of place holders PH, and the substrate 102 may be etched by using the mask pattern MP1 as an etch mask. Thus, a plurality of wall spaces WS for forming insulating walls (refer to VW in FIGS. 8B and 8C) and a plurality of device isolation spaces IS for forming the field insulating film (refer to 112 in FIGS. 8B and 8C) may be formed on the substrate 102. By removing a portion of the substrate 102, a plurality of semiconductor regions F2, which protrude upward from the substrate 102 in the vertical direction (Z direction), may be formed, and respective portions of the plurality of wall spaces WS and the plurality of device isolation spaces IS may be defined by the plurality of semiconductor regions F2.

As shown in FIG. 24B, a depth of each of the plurality of device isolation spaces IS may be greater than a depth of each of the plurality of wall spaces WS. As a result, a vertical level LV1 of the substrate 102 exposed at the bottom of each of the plurality of device isolation spaces IS may be closer to the backside surface 102B of the substrate 102 than a vertical level LV2 of the substrate 102 exposed at the bottom of each of the plurality of wall spaces WS.

Referring to FIGS. 25A, 25B, and 25C, the mask pattern MP1 may be removed from the resultant structure of FIGS. 24A and 24B, and a plurality of field insulating films 112 filling the plurality of device isolation spaces IS may be formed on the substrate 102. The field insulating film 112 may be formed to cover a sidewall of each of the semiconductor region F2 and the place holder PH in the device isolation space IS. The formation of the field insulating film 112 may include forming an insulating film to such a sufficient thickness so as to fill the plurality of device isolation spaces IS on the resultant structure of FIGS. 24A and 24B, and performing a recess process of removing a portion of the insulating film to form the field insulating film 112 that includes the remaining portion of the insulating film. After the field insulating film 112 is formed, the stack structure including the plurality of sacrificial semiconductor layers 104 and the plurality of nanosheet semiconductor layers NS, which remains on the substrate 102, may protrude from a top surface of the field insulating film 112, and a top surface of an uppermost one of the plurality of nanosheet semiconductor layers NS may be exposed.

Thereafter, a plurality of dummy gate structures DGS may be formed to cover the plurality of sacrificial semiconductor layers 104 and the plurality of nanosheet semiconductor layers NS, and first insulating spacers 118 may be formed to cover both sidewalls of each of the plurality of dummy gate structures DGS. Each of the plurality of dummy gate structures DGS may be formed to extend lengthwise in a second lateral direction (Y direction). Each of the plurality of dummy gate structures DGS may include a dummy oxide film D122, a dummy gate layer D124, and a capping layer D126, which are sequentially stacked on the stack structure that includes the plurality of sacrificial semiconductor layers 104 and the plurality of nanosheet semiconductor layers NS.

Afterwards, respective portions of the plurality of sacrificial semiconductor layers 104 and the plurality of nanosheet semiconductor layers NS may be etched by using the plurality of dummy gate structures DGS and a plurality of first insulating spacers 118 as etch masks. As a result, the plurality of nanosheet semiconductor layers NS may be divided into a plurality of nanosheet stacks NSS, each of which includes the first to fourth nanosheets N1, N2, N3, and N4.

Afterwards, a plurality of insulating walls VW may be formed to fill the plurality of wall spaces WS. The plurality of insulating walls VW may be formed by using various methods. In embodiments of the present inventive concept, to form the plurality of insulating walls VW, a planarized sacrificial film may be formed to cover the resultant structure including the plurality of dummy gate structures DGS, the plurality of first insulating spacers 118, and the plurality of nanosheet stacks NSS. The sacrificial film may include a material having an etch selectivity with respect to a material forming an outer surface of the dummy gate structure DGS. For example, the sacrificial film may include a silicon oxide film. Thereafter, a portion of each of the sacrificial film, the plurality of dummy gate structures DGS, and a plurality of field insulating films 112 may be etched to form a plurality of openings corresponding to spaces in which the plurality of insulating walls VW are to be formed, and the plurality of insulating walls VW may be formed to fill the plurality of openings. Thereafter, the sacrificial film may be removed. After the sacrificial film is removed, the plurality of place holders PH may be exposed on both sides of each of the plurality of insulating walls VW in the second lateral direction (Y direction). Although the process of using the sacrificial film to form the plurality of insulating walls VW has been described as an example, the present inventive concept is not limited thereto, and it is capable of various changes and modifications within the scope of the present inventive concept.

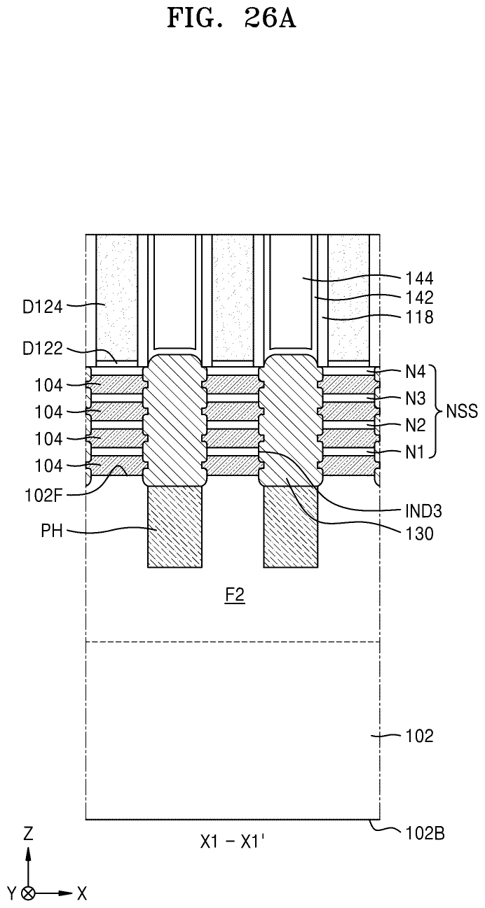

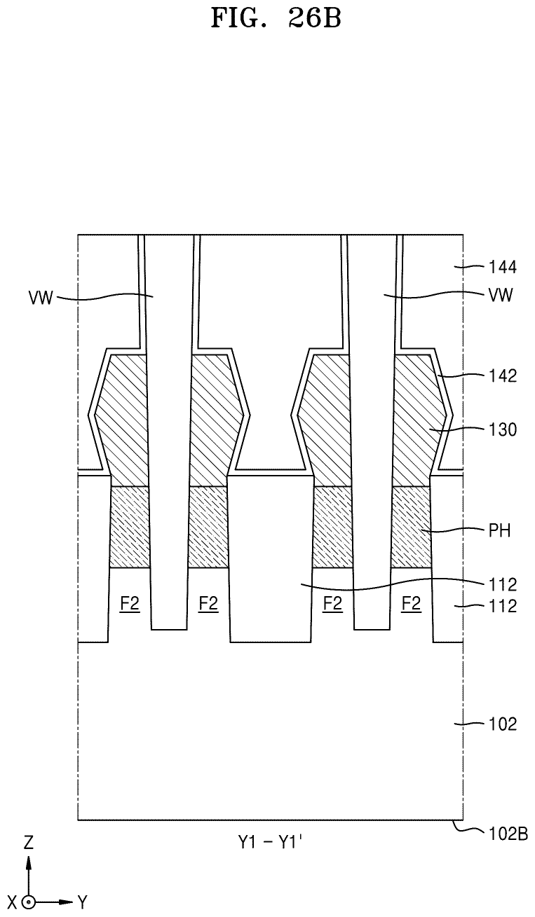

Referring to FIGS. 26A and 26B, by using a method similar to that described with reference to FIG. 12, portions of respective sidewalls of the first to fourth nanosheets N1, N2, N3, and N4 exposed in the resultant structure of FIGS. 25A, 25B, and 25C may be removed to form a plurality of indent spaces IND3, which are indented more inward than respective sidewalls of the plurality of sacrificial semiconductor layers 104 in the first lateral direction (X direction). To form the plurality of indent spaces IND3, by controlling a difference between an etch rate of the first to fourth nanosheets N1, N2, N3, and N4 and an etch rate of the plurality of sacrificial semiconductor layers 104 during the etching of a portion of each of the first to fourth nanosheets N1, N2, N3, and N4, portions of the plurality of sacrificial semiconductor layers 104 exposed at the plurality of indent spaces IND3 may be etched together. As a result, a length of the plurality of indent spaces IND3 in the vertical direction (Z direction) may become greater than a length of each of the first to fourth nanosheets N1, N2, N3, and N4 in the vertical direction (Z direction).

Afterwards, a plurality of source/drain regions 130 may be formed on top surfaces of the plurality of place holders PH that are exposed. To form the plurality of source/drain regions 130, a semiconductor material may be epitaxially grown from the respective sidewalls of the first to fourth nanosheets N1, N2, N3, and N4, which are exposed through the plurality of indent spaces IND3, and an exposed surface of each of the plurality of indent spaces IND3. When the plurality of place holders PH includes a SiGe film, the semiconductor material may be epitaxially grown from surfaces of the plurality of place holders PH during the formation of the plurality of source/drain regions 130.

Thereafter, an insulating liner 142 may be formed to cover surfaces of the resultant structure including the plurality of source/drain regions 130, and an inter-gate dielectric film 144 may be formed on the insulating liner 142. Next, a portion of each of the insulating liner 142 and the inter-gate dielectric film 144 may be etched to expose a top surface of each of the plurality of capping layers (refer to D126 in FIGS. 25A and 25C) and the plurality of insulating walls VW. Afterwards, a portion of each of the plurality of insulating walls VW and the plurality of capping layers D126 may be removed to expose the dummy gate layer D124, and the insulating liner 142 and the inter-gate dielectric film 144 may be partially removed such that a top surface of the inter-gate dielectric film 144, the top surfaces of the plurality of insulating walls VW, and a top surface of the dummy gate layer D124 are substantially at the same level as each other.

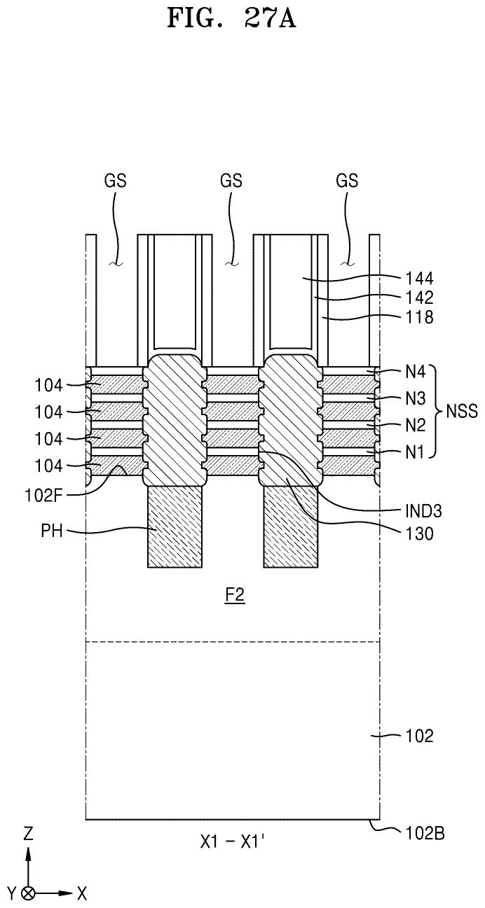

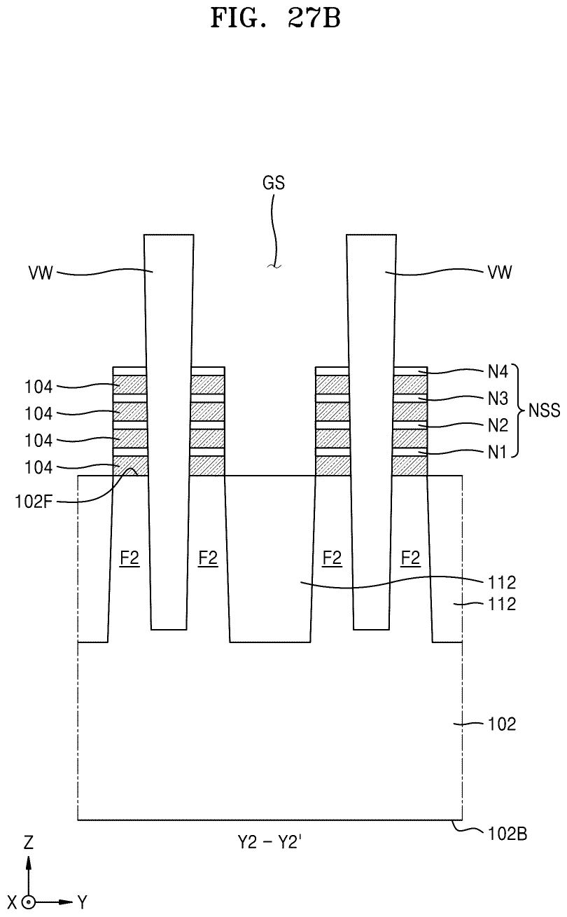

Referring to FIGS. 27A and 27B, the dummy gate layer D124 and the dummy oxide film D122 may be removed from the resultant structure of FIGS. 26A and 26B to provide a gate space GS.

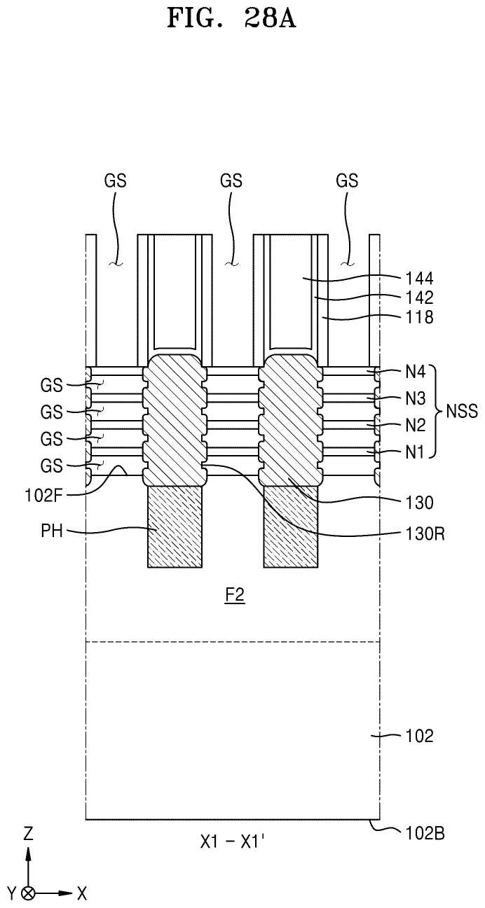

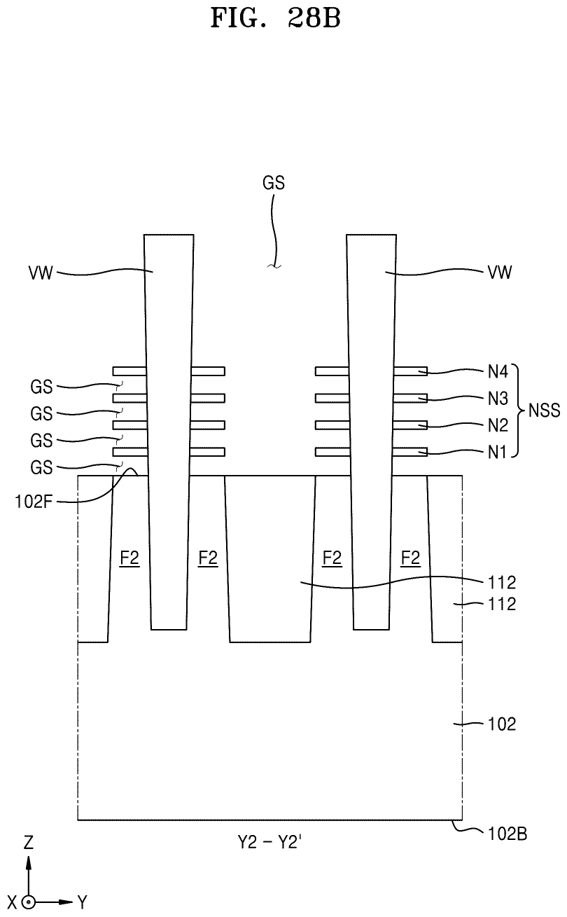

Referring to FIGS. 28A and 28B, by using a method similar to that described with reference to FIGS. 15A and 15B, the plurality of sacrificial semiconductor layers 104 remaining on the substrate 102 may be selectively removed through the gate space GS from the resultant structure of FIGS. 27A and 27B, and thus, the gate space GS may extend to respective spaces between the first to fourth nanosheets N1, N2, N3, and N4 and a space between the semiconductor region F2 and the first nanosheet N1.

After the plurality of sacrificial semiconductor layers 104 are removed, a side recess portion 130R may be exposed at each of the plurality of source/drain regions 130. A length of the side recess portion 130R in the vertical direction (Z direction) may be less than a length of a space between two adjacent ones of the first to fourth nanosheets N1, N2, N3, and N4 in the vertical direction (Z direction).

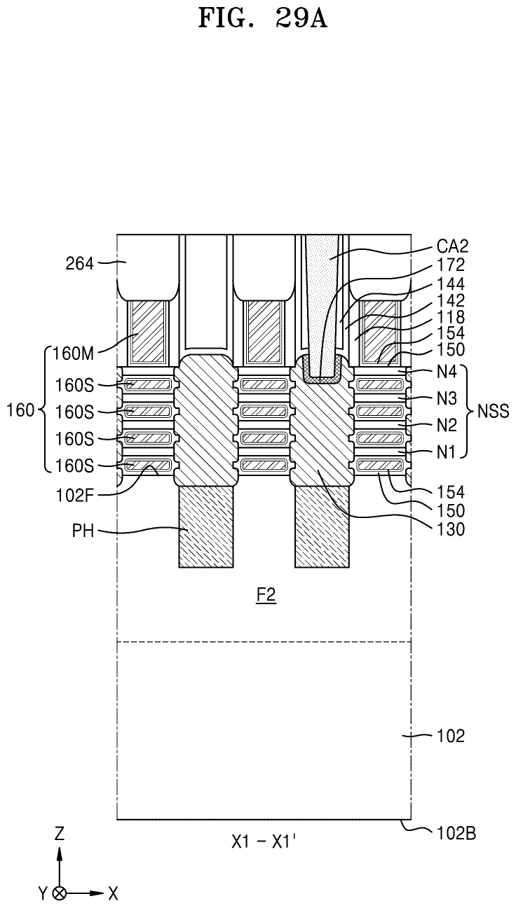

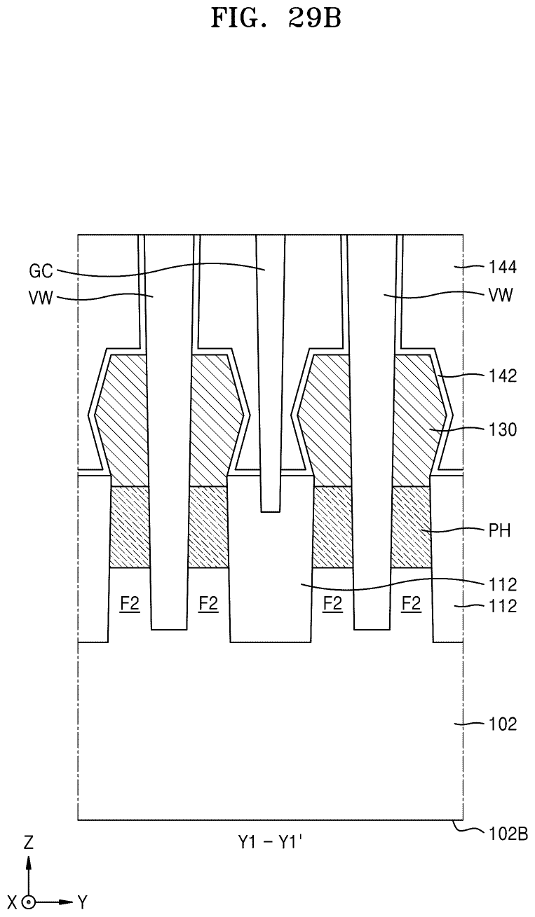

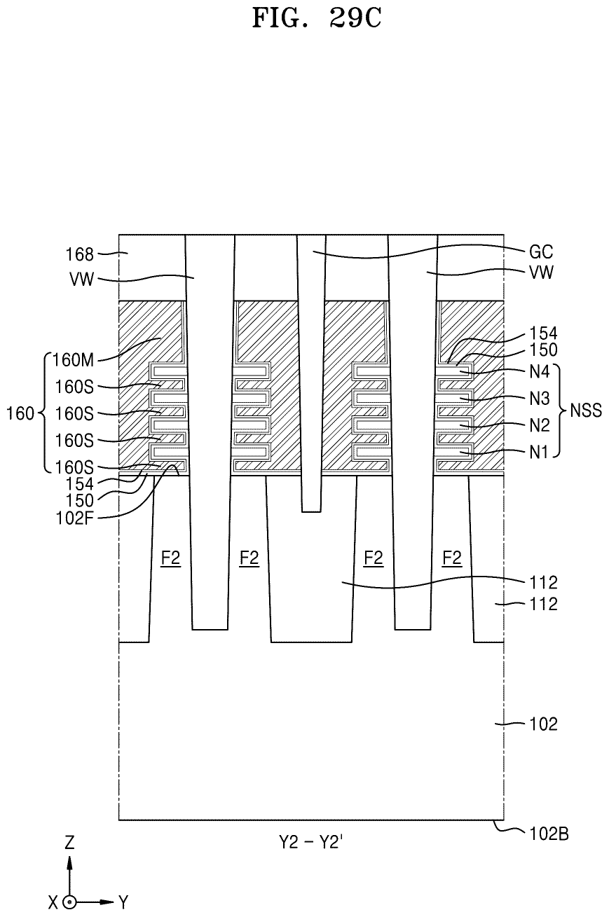

Referring to FIGS. 29A, 29B, and 29C, processes similar to those described with reference to FIGS. 16 to 18B may be performed on the resultant structure of FIGS. 28A and 28B.

More specifically, initially, by using a method similar to that described with reference to FIG. 16, an interface insulating film 150 may be formed to cover respective exposed surfaces of the first to fourth nanosheets N1, N2, N3, and N4 and the plurality of semiconductor regions F2 in the resultant structure of FIGS. 28A and 28B. During the formation of the interface insulating film 150, a relatively small space that is defined by the side recess portion 130R of each of the plurality of source/drain regions 130 may be filled by the interface insulating film 150. Thus, a thickness in the first lateral direction (X direction) of a first inner spacer portion 150A filling the space that is defined by the side recess portion 130R, of the interface insulating film 150, may become greater than a thickness in the first lateral direction (X direction) of a second inner spacer portion 150B extending from the first inner spacer portion 150A toward one nanosheet adjacent thereto, from among the first to fourth nanosheets N1, N2, N3, and N4.

Thereafter, by using a method similar to that described with reference to FIGS. 17A and 17B, a high-k dielectric film 154 may be formed to conformally cover a surface of the interface insulating film 150.

Subsequently, by using a method similar to that described with reference to FIGS. 18A and 18B, a gate line 160 filling the gate space (refer to GS in FIGS. 28A and 28B) may be formed on the high-k dielectric film 154.

Afterwards, a portion of each of the gate line 160, the interface insulating film 150, the high-k dielectric film 154, and the first insulating spacer 118 may be removed from a top surface thereof to reduce a height of each of the gate line 160, the interface insulating film 150, the high-k dielectric film 154, and the first insulating spacer 118, and a capping insulating pattern 264 may be formed to cover the top surface of each of the gate line 160, the interface insulating film 150, the high-k dielectric film 154, and the first insulating spacer 118.

Thereafter, a source/drain contact hole exposing the source/drain region 130 may be formed between two adjacent ones of the plurality of gate lines 160, a metal silicide film 172 may be formed on a surface of the source/drain region 130 through the source/drain contact hole, and a frontside source/drain contact CA2 filling the source/drain contact hole may be formed on the metal silicide film 172.

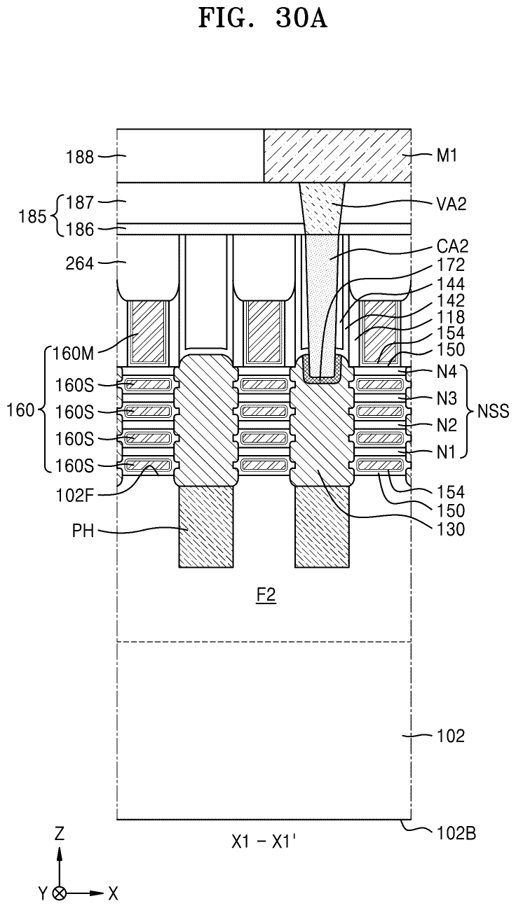

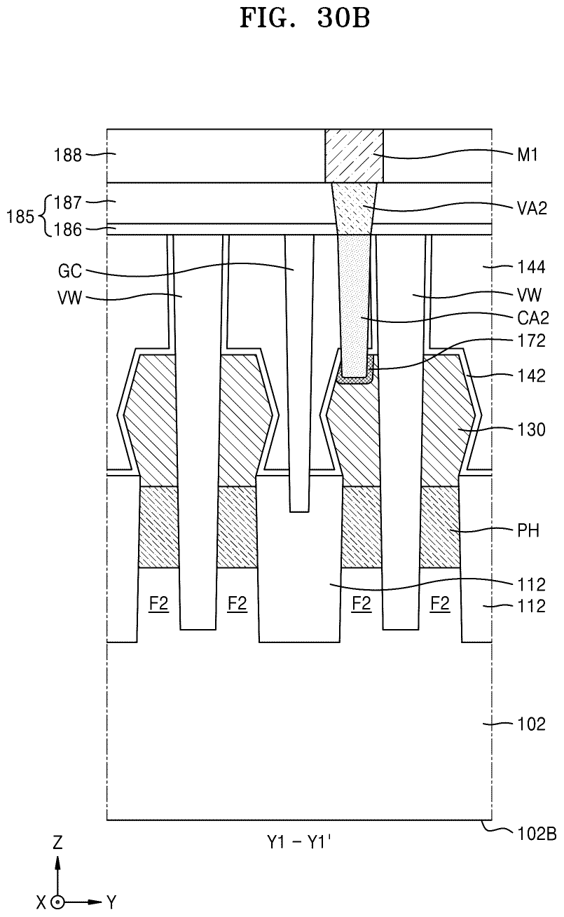

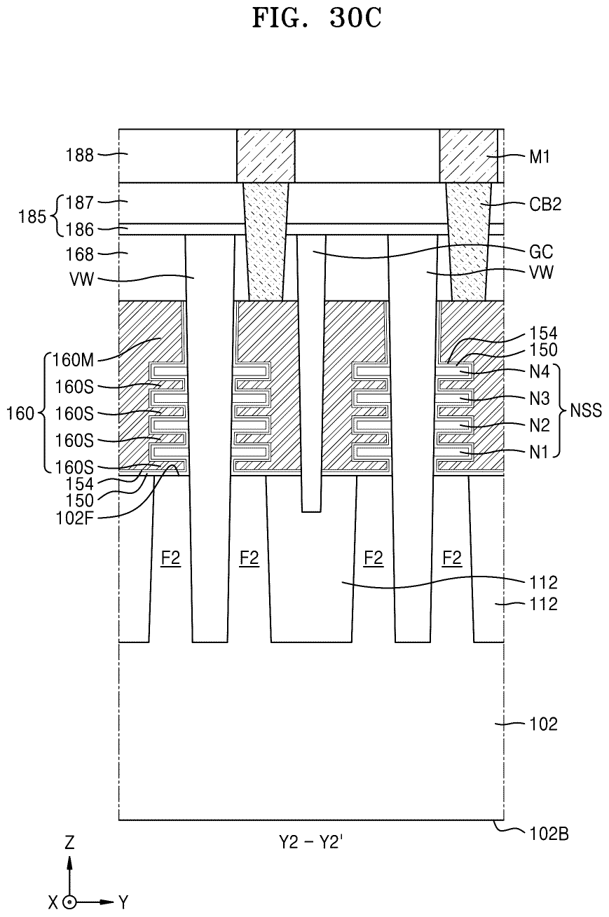

Referring to FIGS. 30A, 30B, and 30C, in the resultant structure of FIG. 29A, 29B, and 29C, an etch stop film 186 and an upper insulating film 187 may be sequentially formed to cover a top surface of each of the frontside source/drain contact CA2, a plurality of capping insulating patterns 264, the plurality of insulating walls VW, and the inter-gate dielectric film 144 to form an upper insulating structure 185. Afterwards, a source/drain via contact VA2 may be formed to pass through the upper insulating structure 185 in the vertical direction (Z direction) and be connected to the frontside source/drain contact CA2. A gate contact CB2 may be formed to pass through the upper insulating structure 185 and the capping insulating pattern 264 in the vertical direction (Z direction) and may be connected to the gate line 160. The source/drain via contact VA2 and the gate contact CB2 may be formed simultaneously or by using separate processes from each other. Subsequently, a frontside interlayer insulating film 188 covering the upper insulating structure 185 and a plurality of upper wiring layers M1 passing through the frontside interlayer insulating film 188 may be formed. The plurality of upper wiring layers M1 may include an upper wiring layer M1 connected to the source/drain via contact VA2 and an upper wiring layer M1 connected to the gate contact CB2. Thereafter, a frontside wiring structure may be formed on the frontside interlayer insulating film 188 and the plurality of upper wiring layers M1.

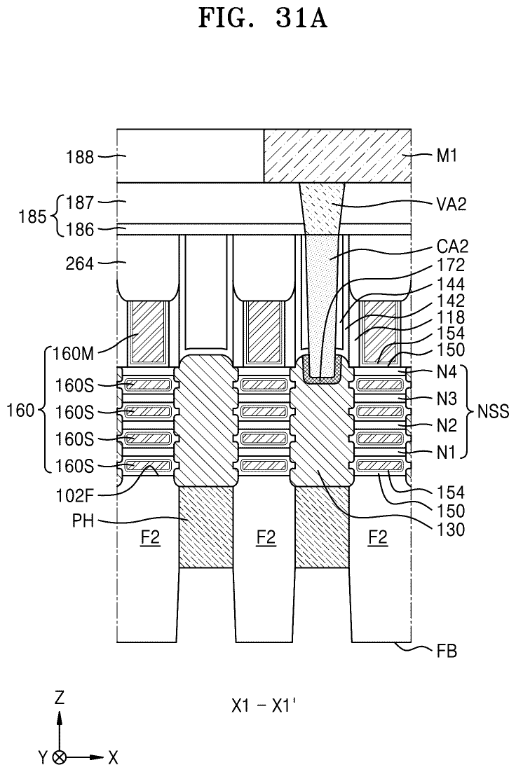

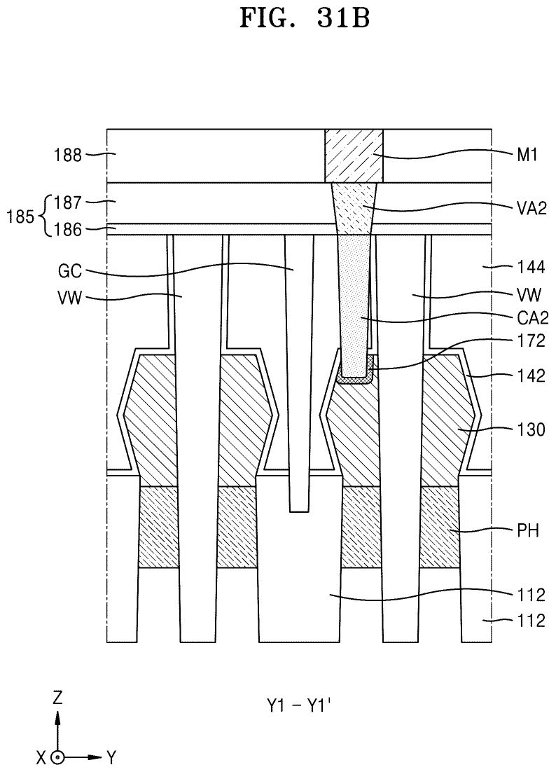

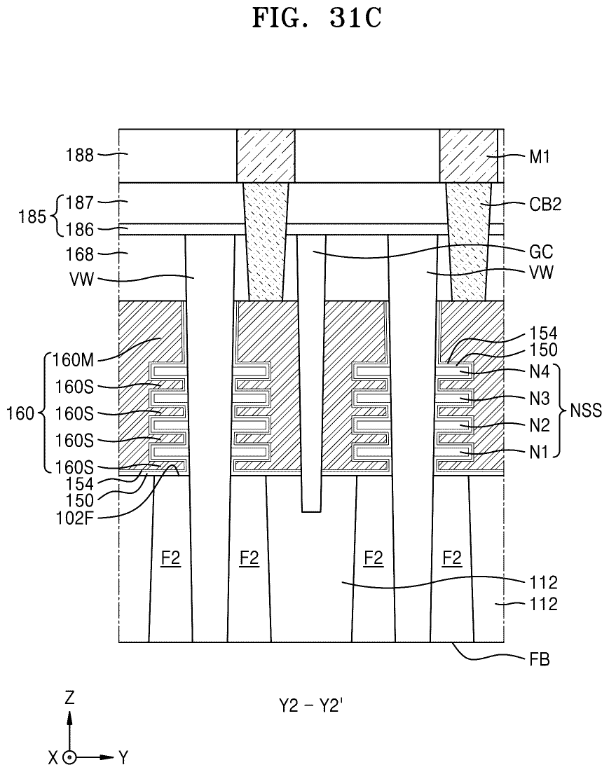

Referring to FIGS. 31A, 31B, and 31C, in the resultant structure of FIGS. 30A, 30B, and 30C, the substrate 102 may be polished from the backside surface 102B of the substrate 102, and portions of the plurality of semiconductor regions F2 may be removed to expose the plurality of place holders PH.

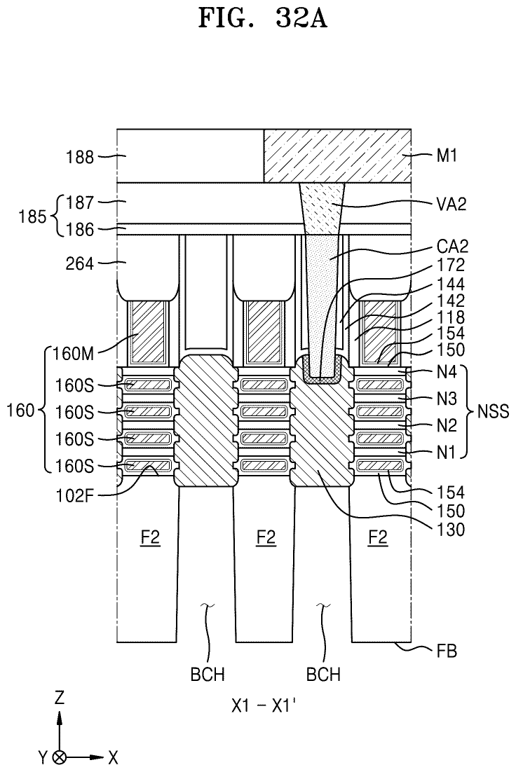

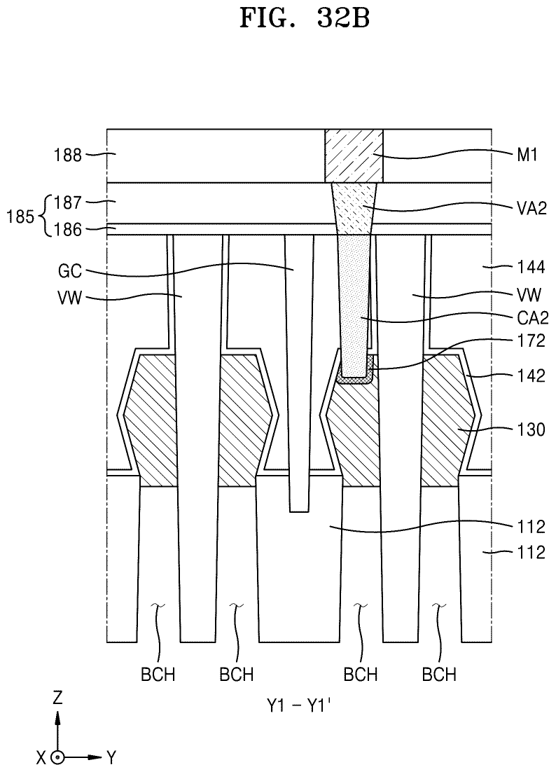

Referring to FIGS. 32A and 32B, the plurality of place holders PH may be removed from the resultant structure of FIGS. 31A, 31B, and 31C to form a plurality of backside contact holes BCH exposing the plurality of source/drain regions 130.

A width of each of the plurality of backside contact holes BCH in the first lateral direction (X direction) may be defined by two adjacent ones of the plurality of semiconductor regions F2, and a width of each of the plurality of backside contact holes BCH in a second lateral direction (Y direction) may be defined by the field insulating film 112 and the insulation wall VW. In the first lateral direction (X direction) and the second lateral direction (Y direction), a width of each of the plurality of backside contact holes BCH may gradually increase as the backside surface FB of the semiconductor region F2 is approached.

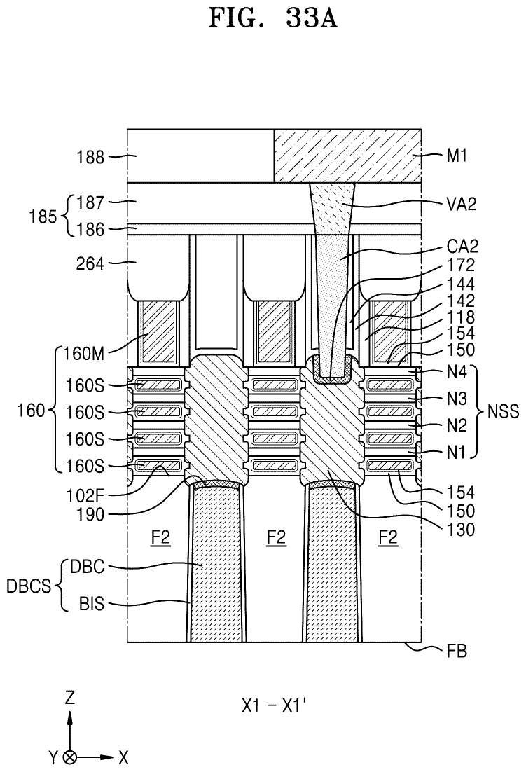

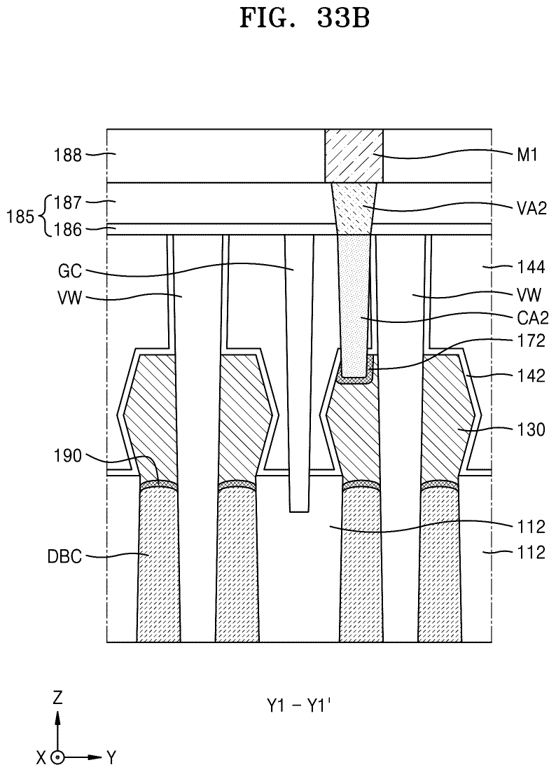

Referring to FIGS. 33A and 33B, in the resultant structure of FIGS. 32A and 32B, a backside insulating spacer BIS may be formed to cover a surface of the semiconductor region F2, which is exposed at an inner sidewall of each of the plurality of backside contact holes BCH. The plurality of backside contact holes BCH, each of which is defined by the backside insulating spacer BIS, the field insulating film 112, and the insulation wall VW, may be filled by a conductive material to form a plurality of backside contact structures DBCS.

While the present inventive concept has been described with reference to embodiments thereof, it will be understood by those of ordinary skill in the art that various changes in form and details may be made thereto without departing from the spirit and scope of the present inventive concept.

What is claimed is:

1. An integrated circuit device comprising:
a fin-type active region extending lengthwise in a first direction on a substrate;
a nanosheet disposed on the fin-type active region;
a gate line surrounding the nanosheet on the fin-type active region, wherein the gate line overlaps the nanosheet in a vertical direction;
a source/drain region disposed on the fin-type active region, wherein the source/drain region contacts the nanosheet; and
an interface insulating film surrounding the gate line,
wherein the interface insulating film comprises an inner spacer portion disposed between a sidewall of the gate line and the source/drain region,
wherein the inner spacer portion of the interface insulating film comprises:
a first inner spacer portion protruding toward the source/drain region, while covering the sidewall of the gate line and while spaced apart from the nanosheet, wherein the first inner spacer portion has a first thickness in the first direction; and
a second inner spacer portion extending from the first inner spacer portion toward the nanosheet and contacting the nanosheet, wherein the second inner spacer portion has a second thickness in the first direction, wherein the second thickness is less than the first thickness.

2. The integrated circuit device of claim 1, wherein a height of the first inner spacer portion in the vertical direction is greater than or equal to a height of the second inner spacer portion.

3. The integrated circuit device of claim 1, wherein the interface insulating film further comprises a gate insulating portion that is between the gate line and the nanosheet, and
a third thickness of the gate insulating portion in the vertical direction is less than the first thickness.

4. The integrated circuit device of claim 1, further comprising a high-k dielectric film located between the gate line and the interface insulating film,
wherein the high-k dielectric film comprises a high-k dielectric film side portion disposed between the gate line and the first inner spacer portion and between the second inner spacer portion the gate line, and
a thickness of the high-k dielectric film side portion of the high-k dielectric film in the first direction is less than the first thickness.

5. The integrated circuit device of claim 1, wherein the first inner spacer portion has a first height in the vertical direction in the interface insulating film, and
the first height of the first inner spacer portion is less than the first thickness.

6. The integrated circuit device of claim 1, wherein the first inner spacer portion has a first height in the vertical direction in the interface insulating film, and
the first height of the first inner spacer portion is greater than the first thickness.

7. The integrated circuit device of claim 1, wherein the gate line has a shape with a length in the vertical direction gradually reducing toward the sidewall of the gate line in the first direction, and
a partial region of the gate line, adjacent to the sidewall of the gate line, overlaps the second inner spacer portion in the vertical direction.

8. The integrated circuit device of claim 1, wherein the source/drain region comprises a side recess portion that accommodates the first inner spacer portion of the interface insulating film.

9. The integrated circuit device of claim 1, wherein, in a cross-section taken in a second direction that is substantially perpendicular to the first direction, the interface insulating film surrounds the nanosheet without being cut off between the nanosheet and the gate line.

10. The integrated circuit device of claim 1, further comprising an insulation wall contacting a first sidewall of the nanosheet in a second direction that is substantially perpendicular to the first direction,
wherein the interface insulating film comprises a first interface insulating film portion and a second interface insulating film portion, wherein the first interface insulating film portion surrounds surfaces of the nanosheet without surrounding the first sidewall of the nanosheet, and is disposed between the nanosheet and the gate line, wherein the second interface insulating film portion contacts the insulation wall and is located between the insulation wall and the gate line.

11. An integrated circuit device comprising:
a fin-type active region extending lengthwise in a first direction on a substrate;
a nanosheet stack facing a fin top surface of the fin-type active region, wherein the nanosheet stack comprises a plurality of nanosheets at different vertical distances apart from the fin top surface of the fin-type active region;
a gate line surrounding the plurality of nanosheets on the fin-type active region, and extending in a second direction, wherein the gate line comprises a sub-gate portion disposed between two nanosheets adjacent to each other in a vertical direction, from among the plurality of nanosheets, wherein the second direction is substantially perpendicular to the first lateral direction;
a pair of source/drain regions on both sides of the gate line on the fin-type active region, wherein the pair of source/drain regions contact the plurality of nanosheets;
an interface insulating film surrounding the gate line; and
a high-k dielectric film disposed between the gate line and the interface insulating film,
wherein the interface insulating film comprises a pair of inner spacer portions covering both sidewalls of the sub-gate portion between the pair of source/drain regions,
wherein each of the pair of inner spacer portions of the interface insulating film comprises:
a first inner spacer portion protruding toward one of the pair of source/drain regions, while covering the sidewall of the sub-gate portion and while spaced apart from the plurality of nanosheets, wherein the first inner spacer has a first thickness in the first lateral direction; and
a second inner spacer portion extending from the first inner spacer portion toward a selected one of the plurality of nanosheets and contacting the one nanosheet, wherein the second inner spacer portion has a second thickness in the first direction, wherein the second thickness is less than the first thickness.

12. The integrated circuit device of claim 11, wherein the first inner spacer portion protrudes by about 0.5 nm to about 4 nm beyond than the second inner spacer portion in a direction away from the sub-gate portion in the first direction.

13. The integrated circuit device of claim 11, wherein the two nanosheets that are spaced apart from each other with the sub-gate portion disposed therebetween in the vertical direction, from among the plurality of nanosheets, are a first separation distance apart from each other in the vertical direction, and
a height of the first inner spacer portion in the vertical direction is about 0.2 times or more the first separation distance and is less than the first separation distance.

14. The integrated circuit device of claim 11, wherein the interface insulating film comprises a silicon oxide film.

15. The integrated circuit device of claim 11, wherein, in the interface insulating film, the first inner spacer portion has a first height in the vertical direction, and
the first height of the first inner spacer portion is less than the first thickness of the first inner spacer portion.

16. The integrated circuit device of claim 11, wherein, in the interface insulating film, the first inner spacer portion has a first height in the vertical direction, and
the first height of the first inner spacer portion is greater than the first thickness of the first inner spacer portion.

17. The integrated circuit device of claim 11, wherein each of the pair of source/drain regions comprises a side recess portion that accommodates the first inner spacer portion of the interface insulating film.

18. The integrated circuit device of claim 11, wherein each of the interface insulating film and the high-k dielectric film surrounds each of the plurality of nanosheets without being cut off between the gate line and each of the plurality of nanosheets.

19. The integrated circuit device of claim 11, further comprising an insulation wall contacting a first sidewall of each of the plurality of nanosheets in the second direction,
wherein the interface insulating film comprises a first interface insulating film portion and a second interface insulating film portion, wherein the first interface insulating film portion surrounds surfaces of each of the plurality of nanosheets without surrounding the first sidewall of each of the plurality of nanosheets, and is disposed between the plurality of nanosheets and the gate line, wherein the second interface insulating film portion contacts the insulation wall and is located between the insulation wall and the gate line.

20. An integrated circuit device comprising:
a fin-type active region extending lengthwise in a first direction on a substrate;
a pair of nanosheets disposed on the fin-type active region, wherein the pair of nanosheets are spaced apart from each other;
a gate line surrounding the pair of nanosheets on the fin-type active region and extending lengthwise in a second direction, wherein the gate line comprises a sub-gate portion between the pair of nanosheets, wherein the second direction is substantially perpendicular to the first direction;
a source/drain region disposed on the fin-type active region, wherein the source/drain region contacts the pair of nanosheets;
an interface insulating film surrounding the gate line; and
a high-k dielectric film disposed between the gate line and the interface insulating film,
wherein the interface insulating film comprises an inner spacer portion disposed between a sidewall of the sub-gate portion and the source/drain region,
wherein the inner spacer portion of the interface insulating film comprises:
a first inner spacer portion protruding toward the source/drain region, while covering the sidewall of the sub-gate portion and while spaced apart from the pair of nanosheets, wherein the first inner spacer portion has a first thickness in the first lateral direction; and
a second inner spacer portion extending from the first inner spacer portion toward a selected one of the pair of nanosheets and contacting the one nanosheet, wherein the second inner spacer portion has a second thickness in the first direction, wherein the second thickness is less than the first thickness,
wherein a height of the first inner spacer portion in the vertical direction is greater than or equal to a height of the second inner spacer portion, and
the first inner spacer portion protrudes by about 0.5 nm to about 4 nm beyond the second inner spacer portion in a direction away from the sub-gate portion in the first direction.
